(19) United States
(12) Patent Application Publication
(10) Pub. No.: US 2017/0032992 A1
(43) Pub. Date: Feb. 2, 2017

(54) SUBSTRATE CARRIER, A METHOD AND A PROCESSING DEVICE

(71) Applicant: Infineon Technologies AG, Neubiberg (DE)

(72) Inventor: Tobias Hoechbauer, Villach (AT)

(21) Appl. No.: 14/814,559

(22) Filed: Jul. 31, 2015

(51) Int. Cl. H01L 21/673; C23C 16/458; C23C 16/46; H01L 21/677; C23C 16/455

(52) U.S. Cl. CPC H01L 21/67383; H01L 21/67353; H01L 21/67739; C23C 16/455; C23C 16/46; C23C 16/458

(57) ABSTRACT

A substrate carrier may include: a carrier plate including a plurality of substrate receiving regions; each substrate receiving region may include at least one first recess portion having a first depth and at least one second recess portion having a second depth, the second depth being greater than the first depth; and a carrier plate mounting structure configured to support the carrier plate.

### TECHNICAL FIELD

Various embodiments relate generally to a substrate carrier, a method and a processing device.

### BACKGROUND

In general, a wafer (also referred as to a substrate) can be processed, e.g. coated, doped or structured, for forming semiconductor chips (also called integrated circuit, IC, chip, or microchip). For handling the wafer during processing, the wafer may be arranged in a wafer pocket of a wafer holder (also referred as to wafer carrier), wherein a wafer holder can also include more than one wafer pocket for holding more than one wafer. The wafer holder needs to sustain elevated temperatures, which the wafer holder may be exposed during processing the wafer. Therefore, the wafer holder typically includes a silicon carbide (SiC) coating, which is high temperature resistant.

The wafer may be processed in semiconductor technology, e.g. in SiC technology, in which an epitaxial SiC layer may be formed on a SiC wafer. In this case, the needed process temperature may also affect the wafer holder, e.g. its SiC coating, which may vaporize partially and deposit on the wafer.

The adsorption of SiC on the wafer backside leads to a SiC wafer backside deposition, which changes the topology of the wafer. For example, the SiC backside deposition may impair further processing steps, as among others may be forming a backside metallization, which may impair the electrical properties of the readily processed chips, e.g. the forward voltage (VR) drop in the produced device. Furthermore, the SiC backside deposition causes substantial local wafer thickness variation which may complicate to focus the wafer accurately for lithography. All these deteriorations can be attributed to the topology changes due to the backside deposition.

Due to the high process temperatures in SiC technology, the wafer may be exposed to high thermal stresses, which may deform the wafer, e.g. bow and/or warp the wafer. The deformation of the wafer may impair the thickness homogeneity of epitaxial layer and the layer doping concentration homogeneity. Further, the deformed wafer tends to a slip out of the wafer pocket, making the process uncontrollable, especially in context with the thickness homogeneity of epitaxial layers formed on the wafer and doping concentration homogeneity. Therefore, the suitability of conventional production environment for epitaxial layer growth in SiC technology is strongly restricted.

Further, in a conventional wafer process environment, the holder rotates around its axis during SiC processing, e.g. during epitaxial layer growth. However, the relative position of the wafer regarding the wafer holder is fixed. In other words, the wafer itself is not rotated regarding the wafer holder. Therefore, the on-wafer thickness and doping profiles exhibit no rotational symmetry and consequently their homogeneity is limited which limits the potential for process improvement.

### SUMMARY

According to various embodiments, a substrate carrier may include: a carrier plate including a plurality of substrate receiving regions; each substrate receiving region includes at least one first recess portion having a first depth and at least one second recess portion having a second depth, the second depth being greater than the first depth; and a carrier plate mounting structure configured to support the carrier plate.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a substrate carrier in a top view according to various embodiments;

FIG. 1B and FIG. 1C respectively show a substrate carrier in a cross sectional view according to various embodiments;

FIG. 2A shows a substrate carrier in a top view according to various embodiments;

FIG. 2B shows a substrate carrier in a cross sectional view according to various embodiments;

FIG. 3A to FIG. 3D respectively show a substrate carrier in a cross sectional view according to various embodiments;

FIG. 4 shows a substrate carrier in a top view according to various embodiments;

FIG. 5A to FIG. 5D respectively show a substrate carrier in a cross sectional view according to various embodiments;

FIG. 6A to FIG. 6C respectively show a substrate carrier in a cross sectional view according to various embodiments;

FIG. 6D shows a supporting element in a top view according to various embodiments;

FIG. 7A to FIG. 7D respectively show supporting elements in a top view according to various embodiments;

FIG. 8 shows a processing device in a cross sectional view according to various embodiments; and

FIG. 9 shows a method in a schematic flow diagram according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

The term “lateral” used with regards to the “lateral” extension of a structure (or of a substrate, a wafer, or a carrier) or “laterally” next to, may be used herein to mean an extension or a positional relationship along a surface of a substrate, a wafer, or a carrier. That means that a surface of a substrate (e.g. a surface of a carrier, or a surface of a wafer) may serve as reference, commonly referred to as the main processing surface of the substrate (or the main processing surface of the carrier or wafer). Further, the term “width” used with regards to a “width” of a structure (or of a structure element) may be used herein to mean the lateral extension of a structure. Further, the term “height” used with regards to a height of a structure (or of a structure element), may be used herein to mean an extension of a structure along a direction perpendicular to the surface of a substrate (e.g. perpendicular to the main processing surface of a substrate). The term “thickness” used with regards to a “thickness” of a layer may be used herein to mean the spatial extension of the layer perpendicular to the surface of the support (the material) on which the layer is deposited. If the surface of the support is parallel to the surface of the substrate (e.g. to the main processing surface) the “thickness” of the layer deposited on the support may be the same as the height of the layer. Further, a “vertical” structure may be referred to as a structure extending in a direction perpendicular to the lateral direction (e.g. perpendicular to the main processing surface of a substrate) and a “vertical” extension may be referred to as an extension along a direction perpendicular to the lateral direction (e.g. an extension perpendicular to the main processing surface of a substrate).

According to various embodiments, one or more semiconductor chips (also called integrated circuit, IC, chip, or microchip) may be formed in or on the wafer (also referred to as substrate), e.g. by processing the wafer, e.g. after the epitaxy process. The epitaxy process may include forming an epitaxial SiC layer on the wafer, e.g. using chemical vapor deposition (CVD). Illustratively, the epitaxial SiC layer may provide a high crystal quality, high purity and/or high homogeneity. The epitaxial SiC layer may be processed further, e.g. doped, structured, coated, electrically connected, etc., to form one or more circuit components of the one or more semiconductor chips.

The semiconductor chips may be singulated from the wafer by removing material from a kerf region of the wafer (also called dicing or cutting the wafer). In other words, the semiconductor chip may be singulated by a wafer dicing process. After the wafer dicing process, the semiconductor chip may be electrically contacted and encapsulated, e.g. by mold materials, into a chip carrier (also called a chip housing) which may then be suitable for use in electronic devices such as computers, light sources or power electronic devices. For example, the semiconductor chip may be bonded to a chip carrier by wires, and the chip carrier may be soldered onto a printed circuit board. Optionally, the substrate may be thinned, e.g. after the epitaxy process and before subsequent process steps and/or before encapsulation. Thinning the wafer may cause higher production costs and, if processed after the epitaxy process, potentially increases failures due to the additional handling of the wafer having a bare epitaxial layer exposed on the front side of the wafer.

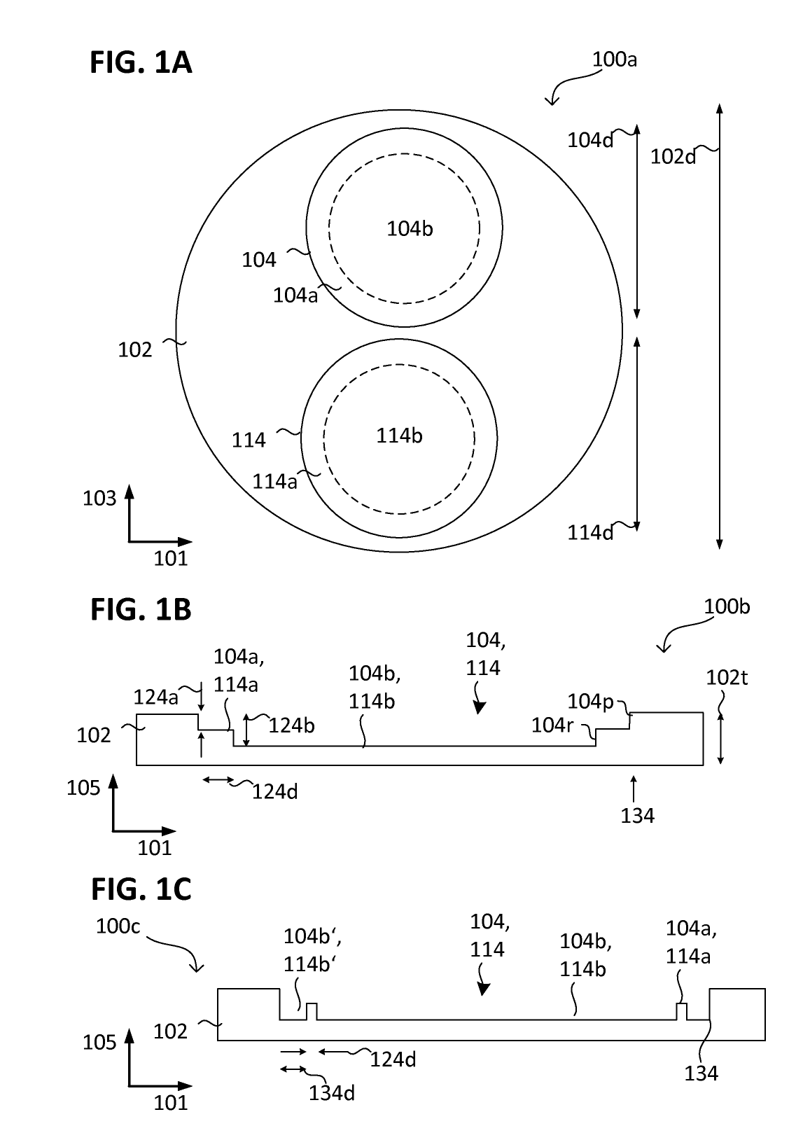

FIG. 1 illustrates a substrate carrier 100a in a top view according to various embodiments, e.g. along a view direction perpendicular to a lateral plate plane (the lateral plate plane may extend into direction 103 and direction 101).

The substrate carrier 100a may include a carrier plate 102. The carrier plate 102 may include of be formed from a material (also referred as to solid material or plate material), which is chemical stable at process temperature, e.g. which remains solid at process temperature. The carrier plate 102 may further include a coating (plate coating), e.g. covering the plate material at least partially. The plate coating may be chemical stable at process temperature, e.g. remaining solid at process temperature. Illustratively, the plate coating may increase the mechanical robustness and/or chemical robustness of the carrier plate 102, e.g. its plate material. For example, the plate coating may avoid diffusion of gases into the carrier plate 102.

The plate material and/or the plate coating may be solid up to a temperature of greater than or equal to 1450° C., e.g. greater than or equal to 1600° C., e.g. greater than or equal to 1800° C., e.g. greater than or equal to 2000° C., e.g. greater than or equal to 2200° C., e.g. in the range from about 1450° C. to 1850° C., e.g. about 1630 C. In other words, the plate material and/or the plate coating may include a state of matter transition (e.g. from solid form to liquid form or from solid form to gaseous form) temperature of greater than or equal to 1450° C., e.g. greater than or equal to 1600° C., e.g. greater than or equal to 1800° C., e.g. greater than or equal to 2000° C., e.g. greater than or equal to 2200° C., e.g. in the range from about 1450° C. to 1850° C., e.g. about 1630 C. The plate material and/or the plate coating may include carbon. The plate material may include or be formed from at least one of carbon, e.g. in the form of graphite, or carbide, e.g. in the form of SiC, the carbide may be optionally polycrystalline. In other words, the plate material may include carbon, e.g. in the form of at least one of graphite or carbide. The plate coating may include or be formed from a carbide material, e.g. silicon carbide and/or tantalum carbide (TaC). Alternatively or additionally, the plate coating may be different from the plate material. According to various embodiments, the plate material may be graphite or SiC.

According to various embodiments, the carrier plate 102 may include a circular-shaped cross section parallel to the lateral plate plane. Alternatively, the carrier plate 102 may include a polygonal cross section parallel to the lateral plate plane, e.g. a hexagonal cross section or a decagonal cross section.

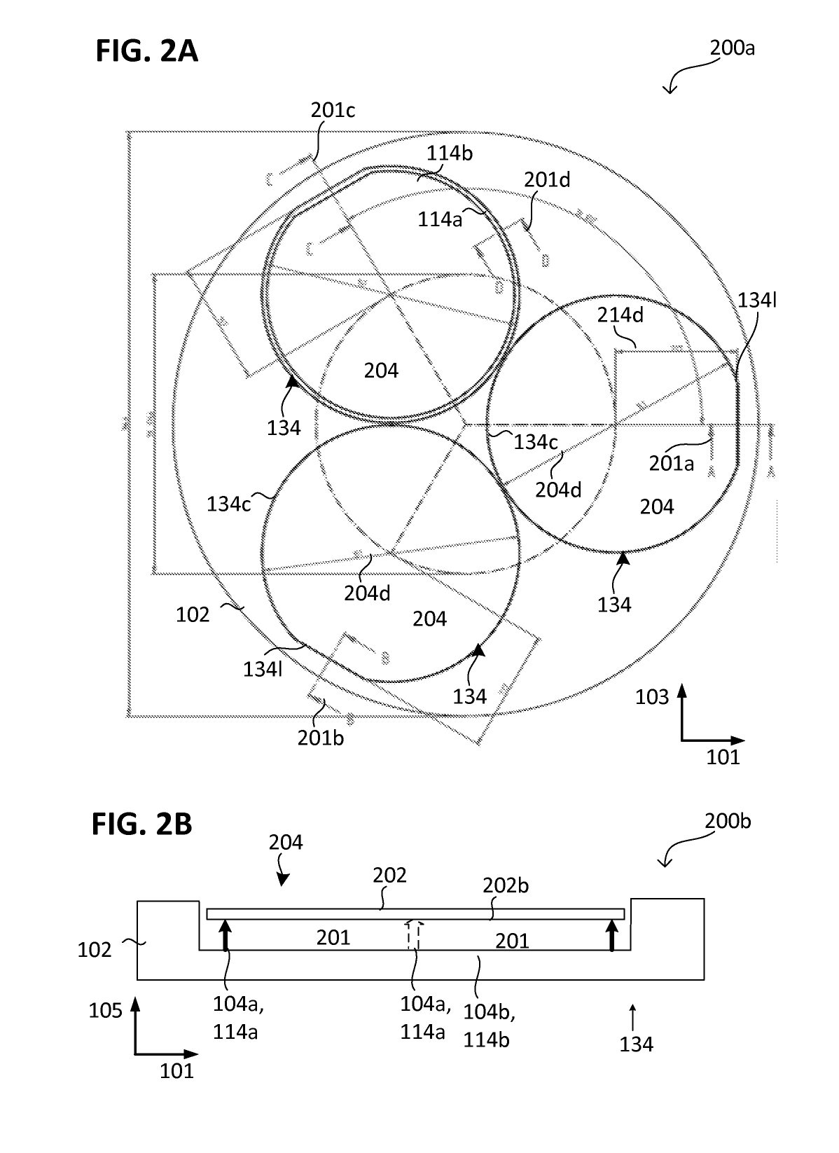

The carrier plate 102 may include a lateral extension 102d (e.g. parallel to the plate plane), e.g. a diameter 204d (see FIG. 2A) in case of a circular-shaped cross section, greater than about 300 mm, e.g. about 344 mm or greater than about 344 mm, e.g. greater than about 350 mm, e.g. greater than about 400 mm, e.g. greater than about 450 mm, e.g. greater than about 500 mm, e.g. greater than about 600 mm, e.g. greater than about 700 mm, e.g. greater than about 800 mm, e.g. in the range from about 300 mm to about 1 m, e.g. in the range from about 300 mm to about 400 mm.

According to various embodiments, the carrier plate 102 may include a plurality of substrate receiving regions 104, 114 (also referred to as wafer pockets), e.g. at least a first substrate receiving region 104 and a second substrate receiving region 114. The first substrate receiving region 104 may include a lateral extension 104d and/or the second substrate receiving region 114 may include a lateral extension 114d (e.g. parallel to the plate plane) of greater than or equal to about 100 mm, e g of greater than or equal to about 150 mm, e.g. of greater than or equal to about 200 mm, e g of greater than or equal to about 250 mm, e.g. of greater than or equal to about 300 mm, e.g. in the range from about 100 mm to about 125 mm (e.g. for processing 100 mm wafer or larger), or in the range from about 125 mm to about 150 mm (e.g. for processing 125 mm wafer or larger), or in the range from about 150 mm to about 200 mm (e.g. for processing 150 mm wafer or larger), or in the range from about 200 mm to about 300 mm (e.g. for processing 200 mm wafer or larger), or in the range from about 300 mm to about 450 mm (e.g. for processing 300 mm wafer or larger), or in the range from about 450 mm to about 500 mm (e.g. for processing 450 mm wafer or larger).

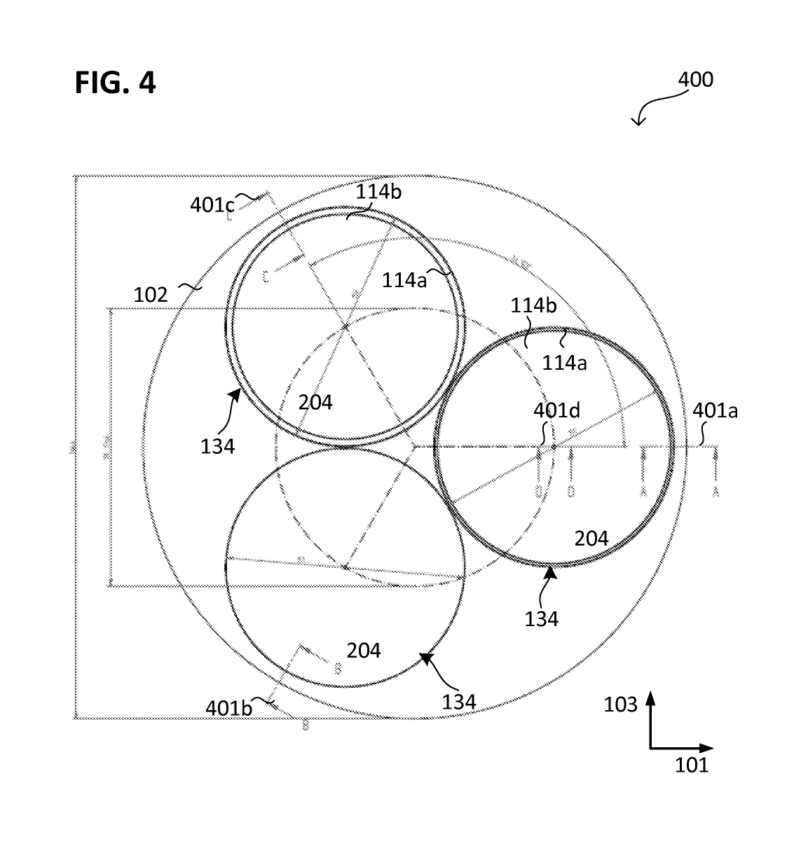

According to various embodiments, the carrier plate 102 may include at least one substrate receiving region (in other words, one substrate receiving region or a plurality of substrate receiving regions). For example, the plurality of substrate receiving regions may include two, three, four, five, six, seven, eight, nine or ten substrate receiving regions, or more than ten substrate receiving regions, e.g. more than 15 substrate receiving regions, e.g. more than 20 substrate receiving regions. The description given for the substrate receiving regions in the following, e.g. for two substrate receiving regions (see FIG. 1A) or for three substrate receiving regions (see FIG. 2A and FIG. 4), may also be adapted to another number of substrate receiving regions, e.g. to one substrate receiving region or each substrate receiving region of a plurality substrate receiving regions. At least one, e.g. each, substrate receiving region may be recessed into the substrate carrier 102. In other words, the substrate carrier 102 may include a recess in at least one, e.g. each, substrate receiving region.

For example, the carrier plate 102 may include about three substrate receiving regions for processing 6 inch substrates or about seven substrate receiving regions for processing 4 inch substrates. For example, the lateral extension 104d, 114d of each substrate receiving region 104, 114 may be smaller than 50% of the lateral extension 102d of the carrier plate 102, e.g. smaller than 30% of the lateral extension 102d of the carrier plate 102. Alternatively, the lateral extension 104d of the substrate receiving region 104 is larger than 50% of the lateral extension 102d of the carrier plate 102, e.g. in the case that the carrier plate 102 includes only one substrate receiving region 104, illustratively, if large substrates have to be processed.

According to various embodiments, the first substrate receiving region 104 and/or the second substrate receiving region 114 may include at least one first recess portion 104a, 114a and at least one second recess portion 104b, 114b. The at least one first recess portion 104a and at least one second recess portion 104b of the first substrate receiving region 104 may be part of a recess in first substrate receiving region 104. The at least one first recess portion 114a and at least one second recess portion 114b of the second substrate receiving region 114 may be part of a recess in second substrate receiving region 114.

Optionally, a surface property of the at least one first recess portion 104a, 114a differs from a surface property of the at least one second recess portion 104b, 114b. For example, the plate coating of the carrier plate 102 in the at least one second recess portion 104b, 114b may be different from the plate coating of the carrier plate 102 in the at least one second recess portion 104b, 114b (e.g. having different chemical compositions, surface roughness and/or surface topology). For example, the plate coating of the carrier plate 102 in the at least one second recess portion 104b, 114b may include or be formed from TaC and the plate coating of the carrier plate 102 in the at least one first recess portion 104a, 114a may include or be formed from SiC, or alternatively the other way around.

Alternatively or additionally, a surface property of the first substrate receiving region 104 and/or the second substrate receiving region 114 differs from a surface property of a portion of the carrier plate 102 outside the first substrate receiving region 104 and/or outside the second substrate receiving region 114, e.g. of the residual carrier plate 102. For example, the plate coating of the carrier plate 102 in the substrate receiving regions 104, 114 may include or be formed from TaC and the plate coating of the carrier plate 102 outside the substrate receiving regions 104, 114 may include or be formed from SiC. This may reduce sublimation of SiC from the plate coating and the corresponding adsorption of SiC by the wafer backside. For example, the carrier plate 102 may include or be formed from SiC and TaC coated graphite (also referred to as hybrid-wafer holder).

According to various embodiments, a perimeter shape of the at least one first recess portion 104a, 114a and/or of the at least one second recess portion 104b, 114b is circular. In other words, the at least one first recess portion 104a, 114a and/or the at least one second recess portion 104b, 114b may include a circular cross section (e.g. parallel to the plate plane). Alternatively, the at least one first recess portion 104a, 114a and/or the at least one second recess portion 104b, 114b may include a polygonal cross section (e.g. parallel to the lateral plate plane), e.g. a hexagonal cross section or a decagonal cross section. Optionally, the at least one first recess portion 104a, 114a and/or the at least one second recess portion 104b, 114b may be segmented. In other words, the at least one first recess portion 104a, 114a and/or the at least one second recess portion 104b, 114b may each include more than one recess portion (having a depth) separated from each other, e.g. by the other recess portion (having a another depth). In this case, the at least one first recess portion 104a, 114a and/or the at least one second recess portion 104b, 114b may include a plurality of recess portions, e.g. two, three, four, five, six, seven, nine, or ten recess portions, or more than ten recess portions, e.g. more than 15 recess portions, e.g. more than 20 recess portions, etc.

FIG. 1B illustrates a substrate carrier 100b in a cross sectional view according to various embodiments, e.g. along a view direction parallel to the carrier plate.

According to various embodiments, the first substrate receiving region 104 and/or the second substrate receiving region 114 may be terraced. In other words, the first substrate receiving region 104 and/or the second substrate receiving region 114 may include a first step at least partially surrounding the at least one first recess portion 104a, 114a and/or a second step at least partially surrounding the at least one second recess portion 104b, 114b (e.g. at their interface). For example, the perimeter of the at least one first recess portion 104a, 114a may include a step and/or the perimeter of the at least one second recess portion 104b, 114b may include a step.

According to various embodiments, the at least one first recess portion 104a, 114a and/or the at least one second recess portion 104b, 114b may include a base surface (e.g. parallel to the carrier plate, e.g. its plate plane). A first sidewall 104p of the at least one first recess portion 104a, 114a (the first sidewall 104r, e.g. including or formed from the first step) may extend between the base surface of the at least one first recess portion 104a, 114a and a top surface of the carrier plate 102. A second sidewall 104p of the at least one second recess portion 104b, 114b (the second sidewall 104r, e.g. including or formed from the second step) may extend between the base surface of the at least one second recess portion 104b, 114b and the base surface of the at least one second recess portion 104b, 114b. The first sidewall 104p of the at least one first recess portion 104a, 114a may define a perimeter of the first substrate receiving region 104 and/or of the second substrate receiving region 114.

According to various embodiments, a first depth 124a of the at least one first recess portion 104a, 114a, in other words, the extension 124a of the at least one first recess portion 104a, 114a into the carrier plate 102 (e.g. along a direction perpendicular to the plate plane), may be less than a second depth 124b of the at least one second recess portion 104b, 114b, in other words, the extension 124a of the at least one second recess portion 104b, 114b into the carrier plate 102 (e.g. along a direction perpendicular to the plate plane).

In other words, the first depth 124a may be different from the second depth 124b. The first depth 124a may correspond to a vertical extension of the first sidewall 104p. The difference between the first depth 124a and the second depth 124b may correspond to a vertical extension of the second sidewall 104r. The difference between the first depth 124a and the second depth 124b may be greater than about 50 μm, e.g. greater than about 75 μm, e.g. greater than about 100 μm, e.g. greater than about 150 μm, e.g. greater than about 200 μm, e.g. greater than about 250 μm, e.g. greater than about 300 μm, e.g. in the range from about 50 μm to 300 μm, e.g. in the range from about 100 μm to 200 μm.

According to various embodiments, the first depth 124a may be less than or equal to about 400 μm, e.g. less than or equal to about 350 μm, e.g. less than or equal to about 300 μm, e.g. in the range from about 300 μm to 400 μm. The first depth 124a may be in the range of the wafer thickness, e.g. equal to the wafer thickness. For example, the wafer thickness may be in the range of 350 μm plus/minus 25 μm. Alternatively, the first depth 124a may be greater than the wafer thickness, e.g. if the wafer tends to slip out of the substrate receiving region 104, 114.

According to various embodiments, the second depth 124b may be greater than about 400 μm, e.g. greater than about 450 μm, e.g. greater than about 500 μm, e.g. greater than about 550 μm, e.g. greater than about 600 μm, e.g. greater than about 700 μm, e.g. greater than about 1 mm, e.g. greater than about 1.5 mm, e.g. greater than about 2 mm, e.g. in the range from about 400 μm to about 4 mm, e.g. in the range from about 400 μm to about 2 mm, e.g. in the range from about 400 μm to about 1 mm, e.g. in the range from about 400 μm to about 600 μm. Illustratively, the second depth 124a may be greater than the wafer thickness, e.g. greater than twice the wafer thickness.

According to various embodiments, the second depth 124b may be correlated to the lateral extension 104d, 114d of the substrate receiving region 104, 114. Illustratively, the second depth 124b may be greater than the thickness of a substrate received in the substrate receiving region 104, 114. A ratio of second depth 124b to the lateral extension 104d, 114d of the substrate receiving region 104, 114 may be greater than or equal to about 2.5·10⁻³, e.g. greater than or equal to about 2.75·10⁻³, e.g. greater than or equal to about 3·10⁻³, e.g. greater than or equal to about 3.25·10⁻³, e.g. greater than or equal to about 3.5·10⁻³, e.g. greater than or equal to about 3.75·10⁻³, e.g. greater than or equal to about 4·10⁻³, e.g. greater than or equal to about 4.25·10⁻³, e.g. greater than or equal to about 4.5·10⁻³, e.g. greater than or equal to about 4.75·10⁻³, e.g. greater than or equal to about 5·10⁻³, e.g. greater than or equal to about 6·10⁻³, e.g. greater than or equal to about 7·10⁻³, e.g. greater than or equal to about 8·10⁻³. Illustratively, the ratio of the second depth 124b to the lateral extension 104d, 114d of the substrate receiving region 104, 114 may define the aspect ratio of the substrate receiving region 104, 114.

In the case, a lateral extension 104d, 114d of the substrate receiving region 104, 114 is less than or equal to about 150 mm, e.g. less than or equal to about 100 mm, the second depth 124b may be greater than about 400 μm, e.g. greater than about 450 μm, e.g. greater than about 500 μm, e.g. greater than about 600 μm, e.g. greater than about 700 μm, e.g. greater than about 800 μm, e.g. in the range from about 400 μm to about 4 mm, e.g. in the range from about 400 μm to about 2 mm, e.g. in the range from about 450 μm to about 1 mm. In the case, a lateral extension 104d, 114d of the receiving region 104, 114 is less than or equal to about 200 mm, the second depth 124b may be greater than about 500 μm, e.g. greater than about 550 μm, e.g. greater than about 600 μm, e.g. greater than about 700 μm, e.g. greater than about 800 μm, e.g. in the range from about 400 μm to about 4 mm, e.g. in the range from about 400 μm to about 2 mm, e.g. in the range from about 450 μm to about 1 mm.

The term equal to “about” a value, e.g. in context to a lateral extension, may be understood as including a range around the value, e.g. a range of plus or minus 10% of the value, e.g. a range of plus or minus 5% of the value, e.g. a range of plus or minus 1% of the value, e.g. a range of plus or minus 0.5% of the value. For example, a lateral extension equal to about 200 mm may include a lateral extension of 220 mm, a lateral extension of 210 mm, a lateral extension of 202 mm, and a lateral extension of 201 mm. Illustratively, a lateral extension equal to “about” a value in context with a substrate receiving region may be understood as the substrate receiving region being formed such that a wafer having a width of the value fits into the substrate receiving region.

According to various embodiments, the at least one first recess portion 104a, 114a is monolithically connected with the carrier plate 102. In other words, the at least one first recess portion 104a, 114a may be monolithically part of the carrier plate 102. For example, the at least one first recess portion 104a, 114a and/or the at least one second recess portion 104b, 114b may be formed by removing material from the carrier plate 102, e.g. in the first substrate receiving region 104 and/or in the second substrate receiving region 114.

According to various embodiments the carrier plate 102 may include a thickness 102t, e.g. an extension 102t perpendicular to the plate plane, greater than about 1 mm, e.g. greater than about 2 mm, e.g. greater than about 3 mm, e.g. greater than about 4 mm, e.g. greater than about 5 mm, e.g. greater than about 6 mm, e.g. greater than about 10 mm, e.g. in the range from about 2 mm to about 4 mm, e.g. in the range from about 3 mm to about 4 mm, or in the range from about 4 mm to about 10 mm.

According to various embodiments, the at least one first recess portion 104a, 114a at least partially surrounds (in other words, partially or completely surrounds) the at least one second recess portion 104b, 114b. The at least one second recess portion 104b, 114b may extend in a central region of the first substrate receiving region 104 and/or of the second substrate receiving region 114. The at least one first recess portion 104a, 114a may extend in a peripheral region of the first substrate receiving region 104 and/or of the second substrate receiving region 114, e.g. adjacent to a perimeter of the first substrate receiving region 104 and/or of the second substrate receiving region 114.

Optionally, the at least one first recess portion 104a, 114a and/or the at least one second recess portion 104b, 114b may be segmented. In this case, the at least one second recess portion 104b, 114b may partially extend into a peripheral region of the first substrate receiving region 104 and/or of the second substrate receiving region 114, e.g. partially adjacent to a perimeter of the first substrate receiving region 104 and/or of the second substrate receiving region 114.

According to various embodiments, a lateral extension 124d (e.g. parallel to the plate plane, e.g. into a radial direction) of the at least one first recess portion 104a, 114a may be greater than about 1 mm, e.g. greater than about 1.5 mm, e.g. greater than about 2 mm, e.g. greater than about 3 mm, e.g. greater than about 4 mm, e.g. greater than about 5 mm, e.g. greater than about 10 mm, e.g. greater than about 20 mm, e.g. in the range from about 1 mm to about 10 mm, e.g. in the range from about 1 mm to about 5 mm, e.g. in the range from about 2 mm to about 4 mm.

FIG. 1C illustrates a substrate carrier 100b in a cross sectional view according to various embodiments.

According to various embodiments, the first substrate receiving region 104 and/or the second substrate receiving region 114 may include at least two second recess portions 104b, 114b (including at least one peripheral second recess portion 104b′, 114b′ and at least one central second recess portion 104b, 114b), wherein the at least one first recess portion 104a, 114a is disposed (or may extend) between the at least two second recess portions 104b, 114b. Illustratively, the at least one first recess portion 104a, 114a may protrude (in other words, may be in form of a protrusion) into the first substrate receiving region 104 and/or into the second substrate receiving region 114.

In this case, the at least one peripheral second recess portion 104b′, 114b′ may at least partially surround the at least one central second recess portion 104b, 114b and the at least one first recess portion 104a, 114a. The at least one first recess portion 104a, 114a may surround the at least one central second recess portion 104b, 114b. The at least one central second recess portion 104b, 114b may extend in a central region of the first substrate receiving region 104 and/or of the second substrate receiving region 114. The at least one peripheral second recess portion 104b′, 114b′ may extend in a peripheral region of the first substrate receiving region 104 and/or of the second substrate receiving region 114, e.g. adjacent to a perimeter of the first substrate receiving region 104 and/or of the second substrate receiving region 114. The at least one first recess portion 104a may extend in a peripheral region of the first substrate receiving region 104 and/or of the second substrate receiving region 114, e.g. adjacent to the at least one peripheral second recess portion 104b′, 114b′.

According to various embodiments, a lateral extension 124d (e.g. parallel to the plate plane, e.g. into a radial direction) of the at least one first recess portion 104a, 114a may be in the range from about 0.1 mm to about 10 mm, e.g. in the range from about 0.1 mm to about 5 mm, e.g. in the range from about 0.1 mm to about 2 mm, e.g. in the range from about 0.5 mm to about 2 mm, e.g. in the range from about 1 mm to about 2 mm or in the range from about 0.1 mm to about 1 mm.

According to various embodiments, a distance 134d (e.g. parallel to the plate plane, e.g. into a radial direction) between the at least one first recess portion 104a, 114a and the perimeter 134 of the first substrate receiving region 104 and/or the perimeter 134 of the second substrate receiving region 114 may be in the range from about 0.1 mm to about 10 mm, e.g. in the range from about 0.1 mm to about 5 mm, e.g. in the range from about 0.1 mm to about 2 mm, e.g. in the range from about 0.5 mm to about 2 mm, e.g. in the range from about 1 mm to about 2 mm or in the range from about 0.1 mm to about 1 mm.

FIG. 2A illustrates a substrate carrier 200a in a top view according to various embodiments, wherein the substrate carrier 200a includes three substrate receiving regions 204, e.g. for processing 150 mm wafer.

According to various embodiments, a shape of the perimeter 134 (perimeter shape) of each substrate receiving region 204 may include a curved portion 134c and a non-curved portion 1341. The curved portion 134c may correspond to a partially circular shape. The substrate receiving region 204 may include an extension (in FIG. 2A represented by an extension 214d to the center point), e.g. a diameter, in the on-curved portion 1341 which is less than an extension 204d, e.g. a diameter, in the curved portion 134c.

The substrate receiving region 204 at the substrate carrier 200a resembles the shape of the wafer including the main flat of the wafer (corresponding to the non-curved portion 1341). The non-curved portion 1341 holds the wafer in a defined position and orientation regarding the carrier plate 102. In other words, a rotation of the wafer around its own center is prevented. This may provide certain process stability.

FIG. 2B illustrates a substrate carrier 200b in a cross sectional view according to various embodiments, wherein a wafer 202 is received in a substrate receiving region 204 of the substrate carrier 200b.

SiC material adsorbed by the wafer 202 at its backside 202b (wafer backside deposition) may change the topology of the wafer backside. The wafer backside deposition and/or the topology features of the wafer backside deposited film may cause processing difficulties during further wafer processing steps such as lithography, and can also cause a shift of the forward voltage (VF) of the produced device. The transfer of SiC from the carrier plate 102 to the wafer backside 202b and/or the deterioration of the wafer backside surface smoothness may be enhanced due to the wafer backside 202b touching (in other words, direct contacting) the carrier plate 102, e.g. in the substrate receiving region 204 (wafer pocket 204). To reduce the transfer of SiC from the carrier plate 102 and to the wafer backside 202b and to reduce the deterioration of the wafer backside surface smoothness, the wafer 202 is supported (e.g. resting only on) by the rim (peripheral region) of the substrate receiving region 204, e.g. including or formed by the at least one first recess portion 104a, 114a. The main part (central region) of the substrate receiving region 204 may be recessed deeper. In other words, a hollow 201 is formed between the wafer 202 and carrier plate 102 in the at least one second recess portion 104b, 114b, e.g. between the wafer 202 and the base surface of the at least one second recess portion 104b, 114b.

This reduces the direct contact between the wafer and the carrier plate 102 (e.g. its covering), e.g. at least in the substrate receiving region 204. In other words, the direct contact between the wafer 202 and the carrier plate 102 may be reduced in the active area of the wafer 202. Furthermore, a deformation of the wafer 202 (e.g. bow and/or warp) occurring at process temperatures (e.g. in the range from about 1450° C. to 1850° C., e.g. about 1630 C) will cause a shift (illustratively, lowering or heightening) of the wafer 202 (e.g. its surface) in the center region of the wafer 202 (e.g. the active region of the wafer 202), e.g. without exposing the rim of the wafer and/or destabilizing the wafer in its position. The shift of the rim of the wafer 202 (illustratively, peripheral region of the wafer 202) due to a deformation of the wafer 202 may illustratively be negligible. Illustratively, the wafer rim will not protrude out of the substrate receiving region 204, thus improving epitaxial layer thickness uniformity and doping uniformity.

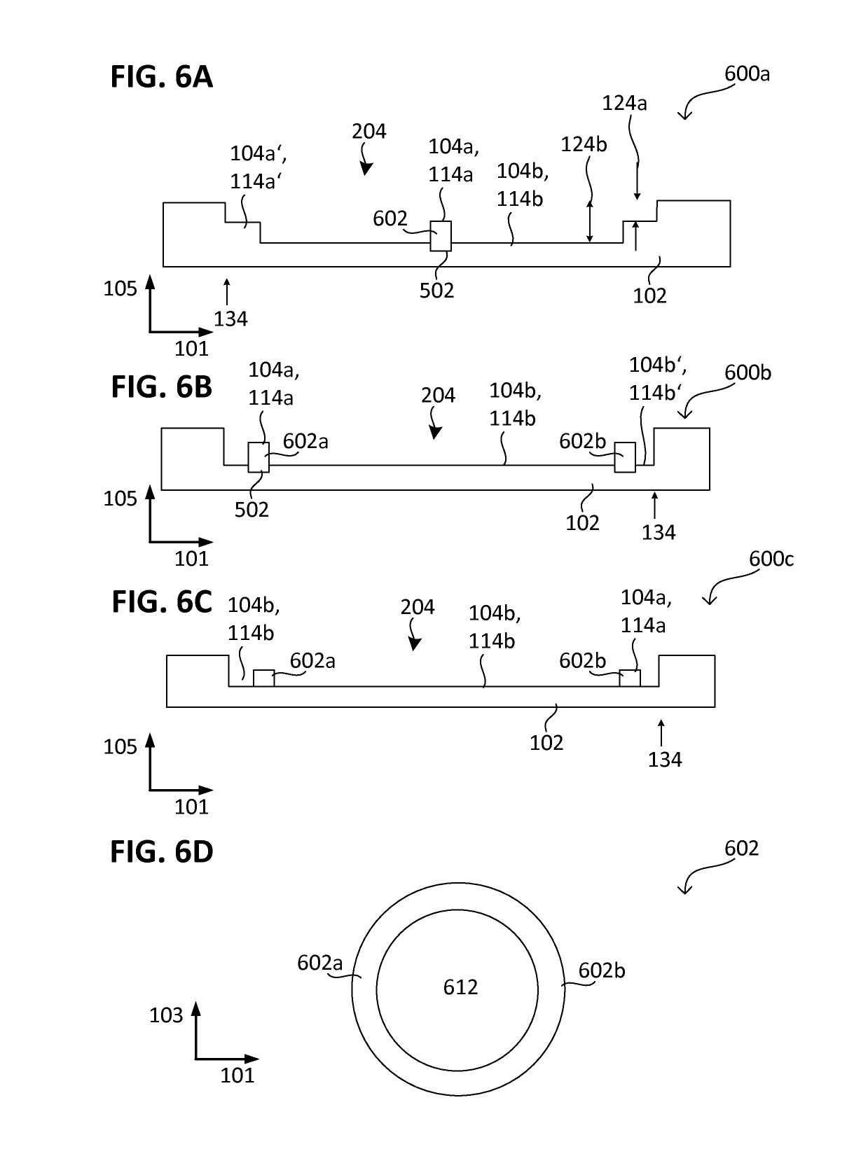

Optionally, at least one further first recess portion 104a, 114a (represented by the dashed arrow) may be disposed in the substrate receiving region 204 (e.g. in the center of the substrate receiving region 204), e.g. in form of a substrate support element 602 (see for example, FIG. 6A).

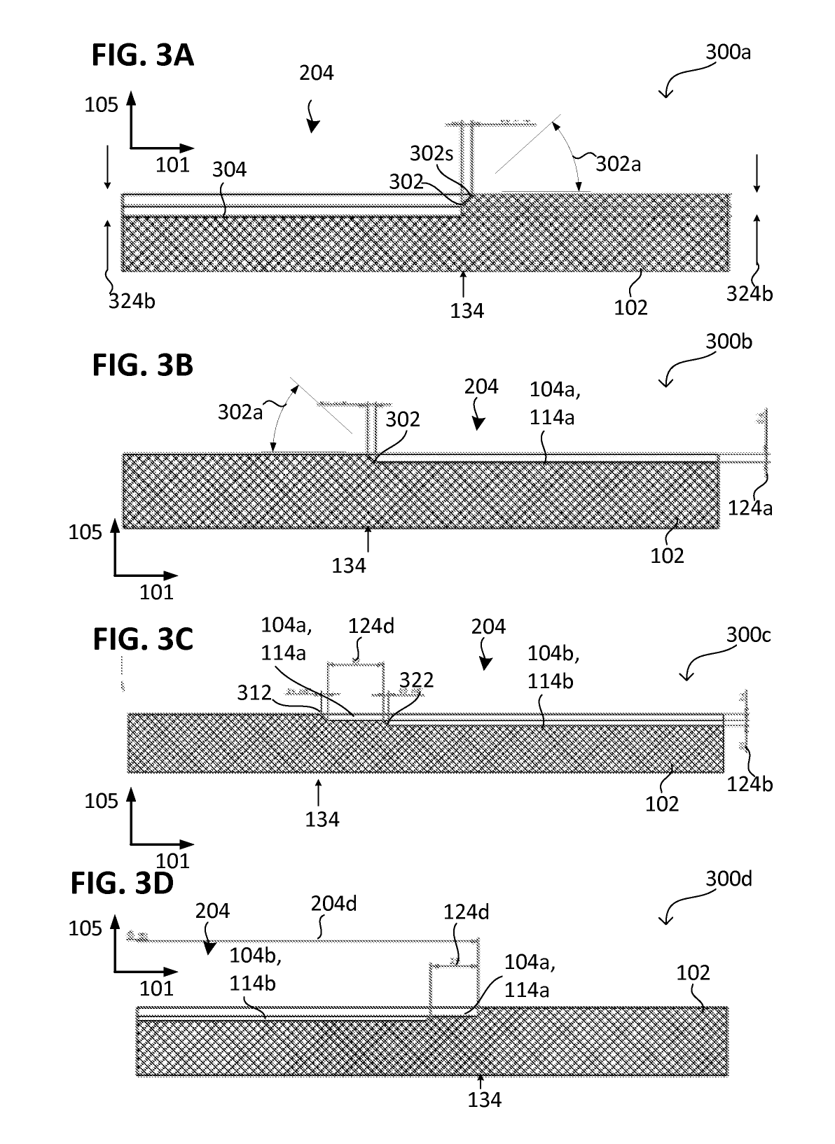

FIG. 3A illustrates a substrate carrier 300a in a cross sectional view according to various embodiments, e.g. along a plane 201a (see FIG. 2A), wherein a sidewall 302 (also referred to as pocket rim) of the substrate receiving region 204 includes optionally a slanted portion 302s. The substrate receiving region 204 may include a recess portion 304 (e.g. a recess) extending into the carrier plate 102. The recess portion 304 may have a lateral extension 204d substantially equal to the lateral extension 204d of the substrate receiving region 204. A depth 324b of the recess portion 304 (in other words, the extension into the carrier plate 102, e.g. perpendicular to the plate plane) may be greater than about 400 μm, e.g. greater than about 450 μm, e.g. greater than about 500 μm, e.g. greater than about 600 μm, e.g. greater than about 700 μm, e.g. greater than about 800 μm, e.g. in the range from about 400 μm to about 4 mm, e.g. in the range from about 400 μm to about 2 mm, e g in the range from about 450 μm to about 1 mm. This may reduce a tendency of a wafer received in the substrate receiving region 204 to slip out.

The substrate receiving region 204 may further include a lateral extension (e.g. parallel to the plate plane) of less than or equal to about 200 mm, e.g. less than or equal to about 125 mm, e.g. less than or equal to about 100 mm, e.g. in the range from about 100 mm to about 125 mm (e.g. for processing 100 mm wafer or larger), or in the range from about 125 mm to about 150 mm (e.g. for processing 125 mm wafer or larger), or in the range from about 150 mm to about 200 mm (e.g. for processing 150 mm wafer or larger). According to various alternative embodiments, the substrate receiving region 204 may include a lateral extension of greater than or equal to about 100 mm, e.g. greater than or equal to about 125 mm, e.g. greater than or equal to about 200 mm, e.g. in the range from about 100 mm to about 125 mm (e.g. for processing 100 mm wafer or larger), or in the range from about 125 mm to about 150 mm (e.g. for processing 125 mm wafer or larger), or in the range from about 150 mm to about 200 mm (e.g. for processing 150 mm wafer or larger), or in the range from about 200 mm to about 300 mm.

According to various embodiments, the depth 324b of the recess portion 304 may by correlated to the lateral extension 204d of the substrate receiving region 204 (e.g. the lateral extension of the recess portion 304). Illustratively, the depth 324b of the recess portion 204 may be greater than the thickness of a substrate received in the substrate receiving region 204. The ratio of the depth 324b of the recess portion 204 to the lateral extension 204d of the substrate receiving region 204 (e.g. the lateral extension 204d of the recess portion 304) may be greater than or equal to about 2.5·10⁻³, e.g. greater than or equal to about 2.75·10⁻³, e.g. greater than or equal to about 3·10⁻³, e.g. greater than or equal to about 3.25·10⁻³, e.g. greater than or equal to about 3.5·10⁻³, e.g. greater than or equal to about 3.75·10⁻³, e.g. greater than or equal to about 4·10⁻³, e.g. greater than or equal to about 4.25·10⁻³, e.g. greater than or equal to about 4.5·10⁻³, e.g. greater than or equal to about 4.75·10⁻³, e.g. greater than or equal to about 5·10⁻³, e.g. greater than or equal to about 6·10⁻³, e.g. greater than or equal to about 7·10⁻³, e.g. greater than or equal to about 8·10⁻³. Illustratively, the ratio of the depth 324b of the recess portion 204 to the lateral extension 204d of the substrate receiving region 204 (e.g. the lateral extension of the recess portion 304) may define the aspect ratio of the substrate receiving region 204 (e.g. its recess portion 304).

In the case, lateral extension 204d of the substrate receiving region 204 (e.g. the lateral extension of its recess portion 304) is less than or equal to about 150 mm, e.g. less than or equal to about 100 mm, the depth 324b of the recess portion 204 may be greater than about 400 μm, e.g. greater than about 450 μm, e.g. greater than about 500 μm, e.g. greater than about 600 μm, e.g. greater than about 700 μm, e.g. greater than about 800 μm, e.g. in the range from about 400 μm to about 4 mm, e.g. in the range from about 400 μm to about 2 mm, e.g. in the range from about 450 μm to about 1 mm. In the case, lateral extension 204d of the substrate receiving region 204 (e.g. the lateral extension of its recess portion 304) is less than or equal to about 200 mm, the depth 324b of the recess portion 204 may be greater than about 500 μm, e.g. greater than about 600 μm, e.g. greater than about 700 μm, e.g. greater than about 800 μm, e.g. in the range from about 400 μm to about 4 mm, e.g. in the range from about 400 μm to about 2 mm, e.g. in the range from about 450 μm to about 1 mm.

According to various embodiments, each substrate receiving region 204 includes a recess portion 304 having a depth of greater than about 400 μm, wherein each substrate receiving region 204 (e.g. its recess portion 304) includes a lateral extension of less than or equal to about 150 mm (e.g. less than 155 mm). Alternatively, each substrate receiving region 204 includes a recess portion 304 having a depth of greater than about 500 μm, wherein each substrate receiving region 204 (e.g. its recess portion 304) includes a lateral extension of less than or equal to about 200 mm (e.g. less than 205 mm).

FIG. 3B illustrates a substrate carrier 300b in a cross sectional view according to various embodiments, e.g. along a plane 201b (see FIG. 2A), wherein a sidewall 302 of the substrate receiving region 204 optionally may be slanted (in other words, the substrate receiving region 204 optionally includes a slanted sidewall 302).

The sidewall 302 may be a sidewall of the at least one first recess portion 104a, 114a (see FIG. 3B) or of the at least one second recess portion 104b, 114b (see FIG. 3A). The sidewall 302 may define a perimeter of the substrate receiving region 204, e.g. at its touching line with a base surface of the substrate receiving region 204.

In other words, the sidewall 302 may include or be formed from at least one surface extending tilted by a first angle 302a with respect to the carrier plate 102, e.g. with respect to the plate plane and/or with respect a base surface of the at least one first recess portion 104a, 114a and/or of the at least one second recess portion 104b, 114b. The first angle may be in the range from about 20° to about 80°, e.g. in the range from about 30° to about 60°, e.g. in the range from about 40° to about 50°.

FIG. 3C illustrates a substrate carrier 300c in a cross sectional view according to various embodiments, e.g. along a plane 201c (see FIG. 2A), wherein a first sidewall 312 of the at least one first recess portion 104a, 114a and a second sidewall 322 of the at least one second recess portion 104b, 114b is slanted, e.g. in a non-curved portion of the substrate receiving region 204. The respective angle by which the first sidewall 312 is tilted and the respective angle by which the second sidewall 322 is tilted may be different or equal, at least one of them may be in the range from about 20° to about 80°, e.g. in the range from about 30° to about 60°, e.g. in the range from about 40° to about 50°.

For example, the lateral extension 124d of the at least one first recess portion 104a, 114a may be in the range from about 3 mm to about 4 mm, e.g. about 3.5 mm. For example, the difference between the first depth and the second depth may be in the range from about 250 μm to about 350 μm, e.g. about 300 μm. For example, the first depth may be in the range from about 350 μm to about 450 μm, e.g. about 400 μm.

The substrate carrier 300c may also include the geometry illustrated in FIG. 3C in a curved portion of the substrate receiving region 204.

FIG. 3D illustrates a substrate carrier 300d in a cross sectional view according to various embodiments, e.g. along a plane 201d (see FIG. 2A), wherein a first sidewall 312 of the at least one first recess portion 104a, 114a and a second sidewall 322 of the at least one second recess portion 104b, 114b is slanted, e.g. in a curved portion of the substrate receiving region 204, similar to FIG. 3C. The substrate carrier 300d may also include the geometry illustrated in FIG. 3D in a non-curved portion of the substrate receiving region 204.

FIG. 4 illustrates a substrate carrier 400 in a top view according to various embodiments, wherein the substrate carrier 400 includes three substrate receiving regions 204, e.g. for processing 6 inch wafer. According to various embodiments, a shape of the perimeter 134 (perimeter shape) of each substrate receiving region 204 may be circular.

In other words, the substrate receiving region 204 may include a circular shape, which may allow a rotation of the wafer in the substrate receiving region 204, e.g. around the center of the wafer. This enables to superposition the rotation of the carrier plate 102 and the rotation of the wafer, resulting in a revolution of the wafer combined with a rotation of the wafer.

According to various embodiments, a friction between the wafer and the carrier plate 102, e.g. its covering, may be reduced. This minimizes the energy or torque required for a rotation of the wafer, e.g. to start the rotation of the wafer. In this context, the movement of gas supported to the wafer, e.g. during processing the wafer, may transfer kinetic energy to the wafer, which may be sufficient to set the wafer in rotation.

Therefore, a surface property of the at least one first recess portion 104a, 114a may differ from a surface property of the at least one second recess portion 104b, 114b. For example, the plate coating of the carrier plate 102 in the at least one second recess portion 104b, 114b may be different from the plate coating of the carrier plate 102 in the at least one second recess portion 104b, 114b (e.g. having different chemical compositions, surface roughness and/or surface topology). For example, a surface roughness of the at least one first recess portion 104a, 114a may be smaller than a surface roughness of the at least one second recess portion 104b, 114b or a surface roughness of the carrier plate 102 outside the substrate receiving regions 204. Alternatively or additionally, a touching area between a wafer and the substrate carrier 400 (in other words, a wafer support area) may be reduced by reducing the lateral extension of the at least one first recess portion 104a, 114a. Alternatively or additionally, a friction (e.g. coefficient of friction) between the substrate and the at least one first recess portion 104a, 114a may be reduced, e.g. compared to friction (e.g. coefficient of friction) between the substrate and the at least one second recess portion 104b, 114b.

Illustratively, the substrate carrier 102 may allow the received wafers to deform (e.g. bow and/or warp) during processing the wafers without detrimental effect on the epitaxial layer homogeneity, and optionally allow a rotation of the wafers around their own center. This may enable to obtain higher on-wafer thickness and higher doping homogeneities.

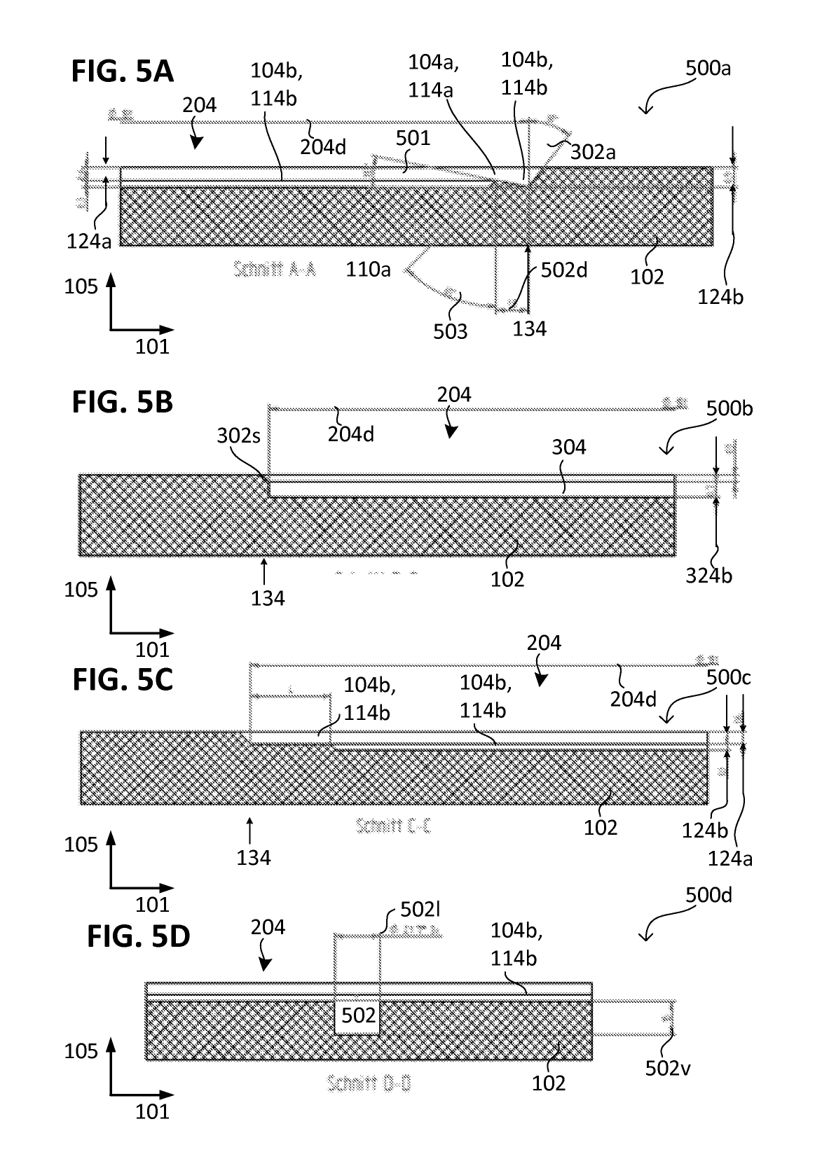

FIG. 5A illustrates a substrate carrier 500a in a cross sectional view according to various embodiments, e.g. along a plane 201a (see FIG. 2A) and/or a plane 401a (see FIG. 4A), wherein the at least one first recess portion 104a, 114a includes a tapered shape, e.g. a tapered cross section (e.g. perpendicular to a plate plane), e.g. a triangular cross section. A tapered shape may, for example, be understood that the in at least one direction (e.g. perpendicular to the plate plane, e.g. against direction 105) a cross section, a width, or a length perpendicular to the direction (e.g. parallel to direction 105) is increasing.

The at least one first recess portion 104a, 114a may include a protrusion, which includes at least two surfaces slanted to each other and to the plate plane. The protrusion may define the first depth, e.g. in the ridge of the protrusion, illustratively, in the highest point of the protrusion. The two surfaces may extend into the at least one first recess portion 104a, 114a and may define an angle between them. For example, a first surface of the two surfaces may extent from the slanted (peripheral) sidewall 302 of the substrate receiving region 204 to the ridge of the protrusion, including an angle 501 with respect to the base surface (e.g. being parallel to a plate plane) of the central recess portion 104b, 114b in the range from about 10° to about 80°, e.g. in the range from about 30° to about 60°, e.g. in the range from about 40° to about 50°. For example, a second surface of the two surfaces may extent from the ridge of the protrusion to the base surface of the central recess portion 104b, 114b, including an angle 503 with respect to a vertical direction (e.g. being perpendicular to a plate plane, e.g. in direction 105) the in the range from about 10° to about 80°, e.g. in the range from about 30° to about 60°, e.g. in the range from about 40° to about 50°. Optionally, at least one second recess portion (not shown) may be disposed between the protrusion and the perimeter 134 of the substrate receiving region 204 (e.g. of the first substrate receiving region 104 and/or of the second substrate receiving region 114).

According to various embodiments, a distance 502d (e.g. parallel to the plate plane, e.g. into a radial direction) between the ridge of the protrusion and the perimeter 134 substrate receiving region 204 may be in the range from about 0.1 mm to about 10 mm, e.g. in the range from about 0.1 mm to about 5 mm, e.g. in the range from about 0.1 mm to about 2 mm, e.g. in the range from about 0.5 mm to about 2 mm, e.g. in the range from about 0.5 mm to about 1 mm.

FIG. 5B illustrates a substrate carrier 500b in a cross sectional view according to various embodiments, e.g. along a plane 401b (see FIG. 4A), e.g. similar to FIG. 3A. The sidewall 302 (also referred to as pocket rim) of the substrate receiving region 204 includes optionally a slanted portion 302s. This enables to minimize the contact between the wafer (its rim) and the substrate carrier 500b. This may illustratively further reduce friction during wafer rotation. The substrate receiving region 204 may be recessed (illustratively disposed deep) into the carrier plate 102, e.g. as a whole, e.g. optionally deeper compared to the carrier 200a (see FIG. 2A). In other words, the first depth 124a and/or second depth 124b of the substrate carrier 500a may optionally be greater than of the carrier 200a. Optionally, at least one further first recess portion (not shown) may be disposed in the substrate receiving region 204, e.g. including or formed by at least one substrate supporting element.

FIG. 5C shows a substrate carrier 500c in a cross sectional view according to various embodiments, e.g. along a plane 401c (see FIG. 4A), e.g. similar to FIG. 3C. The sidewall 302 of the substrate receiving region 204 may optionally be slanted. This enables to minimize the contact between the wafer (its rim) and the substrate carrier 500c. This may illustratively further reduce friction during wafer rotation. The at least one opening 502 may extend into the carrier plate 102, e.g. into a base surface of the substrate receiving region 204. The substrate receiving region 204 may be recessed (illustratively disposed deep) into the carrier plate 102, e.g. as a whole, e.g. optionally deeper compared to the carrier 200a (see FIG. 2A). In other words, the depth 324b of the substrate receiving region 204 of substrate carrier 500a may optionally be greater than of the substrate receiving region 204 of the carrier 200a. This may reduce a tendency of the wafers to slip out of the substrate receiving region 204, e.g. due to their deformation (e.g. bow/warp). Optionally, at least one further first recess portion (not shown) may be disposed in the substrate receiving region 204, e.g. including or formed by at least one substrate supporting element.

FIG. 5D shows a substrate carrier 500d in a cross sectional view according to various embodiments, e.g. along a plane 401d (see FIG. 4A). The substrate receiving region 204 includes at least one opening 502, e.g. in the at least one second recess portion 104b, 114b. The at least one opening 502 may extend into the carrier plate 102, e.g. into a base surface of the substrate receiving region 204. The at least one opening 502 may at least partially be surrounded by the at least one second recess portion 104b, 114b. This may to prevent the wafers to slip out of the substrate receiving region 204, e.g. due to their deformation (e.g. bow/warp).

According to various embodiments, a lateral extension 5021 of the opening 502 (e.g. parallel to the plate plane, e.g. into a radial direction) may be in the range from about 0.1 mm to about 20 mm, e.g. in the range from about 0.5 mm to about 10 mm, e.g. in the range from about 1 mm to about 5 mm.

The at least one opening 502 may be configured to receive at least one supporting element (e.g. in form of a pin). The at least one opening 502 may be disposed in the center of the substrate receiving region 204, e.g. regarding the perimeter of the substrate receiving region 204.

According to various embodiments, a vertical extension 502v (e.g. perpendicular to the plate plane) of at least one opening 502 may be greater than about 0.5 mm, e.g. greater than about 1 mm, e.g. greater than about 1.5 mm, e.g. greater than about 2 mm, e.g. greater than about 3 mm, e.g. in the range from about 0.5 mm to about 3 mm, e.g. in the range from about 1 mm to about 2 mm. Optionally the at least one opening 502 may extend through the carrier plate 102.

According to various embodiments, the at least one opening 502 may provide to receive at least one supporting element (e.g. in form of a pin) independently from its length. In other words, a variety of supporting elements having different lengths, respectively, may be compatible to be received in the at least one opening 502. This may enable to adapt the support geometry according to the substrate geometry (e.g. its thickness, its tendency to deform and/or its tendency to slip out).

FIG. 6A shows a substrate carrier 600a in a cross sectional view (e.g. perpendicular to the plate plane) according to various embodiments. The substrate receiving region 204 may include at least one supporting element 602, e.g. in form of a pin. The at least one supporting element 602 may be detachable. For example, the at least one supporting element 602 may be received in the at least one opening 502, e.g. plugged in or screwed in.

The at least one supporting element 602 may form at least one first recess portion (e.g. at least one central first recess portion 104a, 114a) at least partially (in other words, partially or completely), e.g. in a center of the substrate receiving region 204 (alternatively or additionally, in another position in the substrate receiving region 204). Optionally, the substrate receiving region 204 may include at least one further first recess portion (e.g. at least one peripheral first recess portion 104a′, 114a′). The at least one second recess portion 104b, 114b may be disposed (or may extend) between the at least two first recess portions (between the at least one central first recess portion 104a, 114a and at least one the peripheral first recess portion 104a′, 114a′).

In this case, the at least one peripheral first recess portion 104a′, 114a′ may at least partially surround the at least one central first recess portion 104a, 114a and the at least one second recess portion 104b, 114b. The at least one second recess portion 104b, 114b may surround the at least one central second recess portion 104a, 114a. The at least one central first recess portion 104a, 114a may protrude in a central region of the substrate receiving region 204. The at least one peripheral first recess portion 104a′, 114a′ may adjoin the perimeter 134 of the substrate receiving region 204.

According to various embodiments, in various optional modifications of the substrate carrier 600a, the at least one peripheral first recess portion 104a′, 114a′ may be not necessary, and therefore optionally not part of the substrate receiving region 204 of the substrate carrier 600a. Alternatively or additionally, the substrate receiving region 204 of the substrate carrier 600a may include at least one peripheral second recess portion (not shown), which at least partially surrounds the at least one peripheral first recess portion 104a′, 114a′ (in analogy to FIG. 1C or FIG. 6B). In this case, the at least one peripheral second recess portion may extend between the at least one peripheral first recess portion 104a′, 114a′ and the perimeter 134 of the substrate receiving region 204. Optionally, the at least one peripheral first recess portion 104a′, 114a′ may be segmented.

Optionally, the at least one central first recess portion 104a, 114a (e.g. the at least one supporting element 602) and/or the at least one peripheral first recess portion 104a′, 114a′ may include a tapered shape (not shown, see FIG. 5A). For example, the at least one central first recess portion 104a, 114a (e.g. the at least one supporting element 602) may be formed conical. This may further reduce the contact area of the wafer (also referred as to a substrate) received in the substrate receiving region 204.

According to various embodiments, the at least one central first recess portion 104a, 114a (e.g. the at least one supporting element 602) may have a third depth. The first depth may be greater than the third depth. Illustratively, the at least one supporting element 602 may be higher than the at least one peripheral first recess portion 104a′, 114a′ for supporting a wafer point-like (illustratively in its center) and reduce the friction of the wafer at the rim of the wafer. Alternatively, the first depth may be less than the third depth. Illustratively, the at least one supporting element 602 may be less high than the at least one peripheral first recess portion 104a′, 114a′ for supporting a wafer tending to deform, e.g. allowing the wafer lowering in the central region of the substrate receiving region 204. The third height may be adapted by the length of the at least one supporting element 602 and/or by the vertical extension 502v of at least one opening 502.

The at least one supporting element 602 may support the wafer at its center. This may allow to distribute a weight of the wafer to the at least one supporting element 602. This will further lower the friction which occurs between the wafer and the substrate carrier 600a, e.g. between the wafer and the at least one peripheral first recess portion 104a′, 114a′, e.g. when the wafer rotates. The substrate receiving region 204 may be recessed (illustratively disposed deep) into the carrier plate 102, e.g. as a whole, e.g. optionally deeper compared to the carrier 200a (see FIG. 2A). In other words, the first depth and/or second depth of the substrate carrier 500a may optionally be greater than of the carrier 200a. This may reduce the tendency of the wafers to slip out of the substrate receiving region 204, e.g. due to their deformation (e.g. bow/warp), e.g. during epitaxy processing, e.g. when the wafer is supported by the at least one supporting element 602 in the wafer center.

The supporting element 602 may include a material, which is solid up to a temperature of greater than or equal to 1450° C., e.g. in the range from about 1450° C. to 1850° C., e.g. about 1630 C, e.g. a carbide material (e.g. SiC or TaC) and/or a carbon material (e.g. graphite), e.g. coated by the carbide material. Illustratively, the design of the substrate receiving region 204 enables to position a pin of suitable material (e.g. graphite, SiC. etc.), which supports the wafer at its center, therewith furthermore lowering the friction between wafer holder and wafer at the wafer rim.

According to various embodiments, in various optional modifications, the at least one opening 502 may extend into a carrier plate 102, e.g. into a base surface of the substrate receiving region 204, in at least one of the previously described substrate carriers, e.g. substrate carrier 100a, 200a, 400. Alternatively or additionally, at least one substrate support element (not shown) may be disposed in at least in the substrate receiving region 204, e.g. in the at least one opening 502 if present, e.g. in one of the previously described substrate carrier, e.g. substrate carrier 100a, 200a, 400.

FIG. 6B shows a substrate carrier 600b in a cross sectional view (e.g. perpendicular to the plate plane) according to various embodiments. The substrate receiving region 204 may include at least one supporting element 602.

According to various embodiments, the at least one supporting element 602 may be in form of a ring (see FIG. 6D). In this case, a first portion 602a of the at least one supporting element 602 and a second portion 602b of the at least one supporting element 602 may be connected to each other, e.g. monolithically.

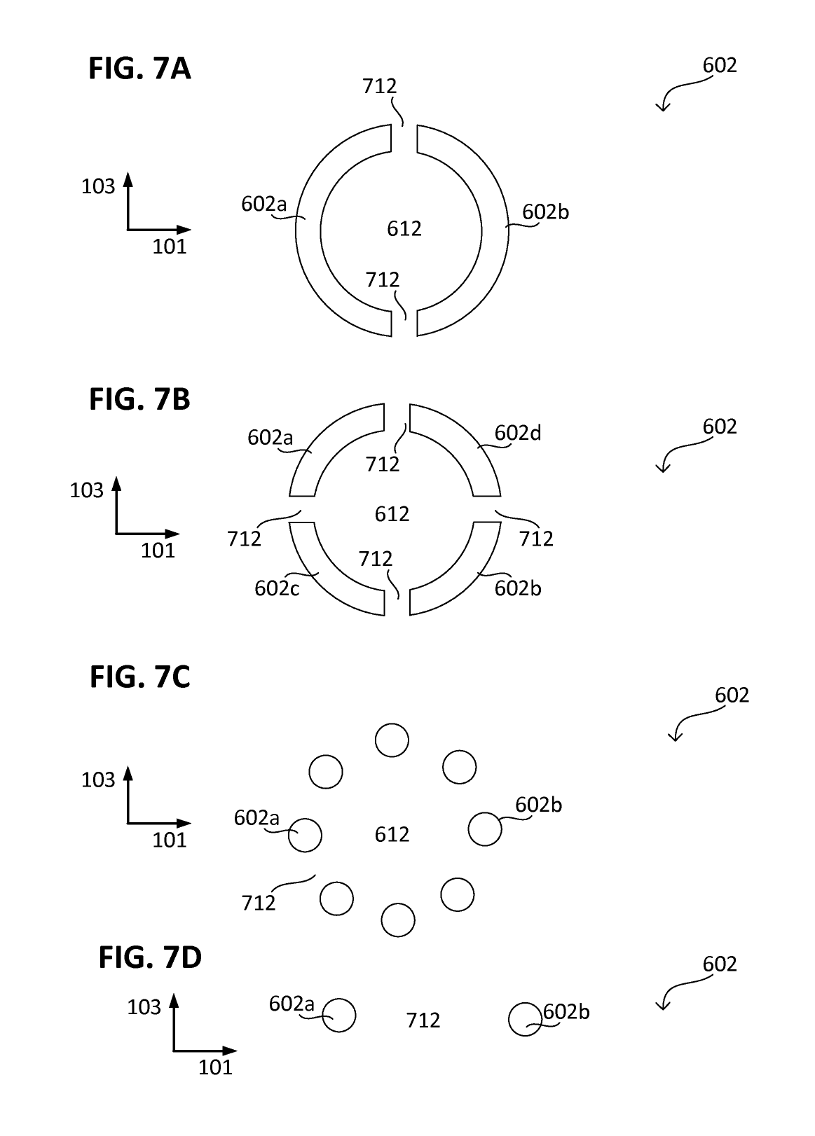

Alternatively, the at least one supporting element 602 may be segmented, in other words, may include a plurality of supporting elements, e.g. a first supporting element 602a and a second supporting element 602b (see FIG. 7A to FIG. 7D). In this case, the first supporting element 602a and the second supporting element 602b may be separated from each other, e.g. by the at least one second recess portion 104b, 114b. In this case, the at least one opening 502 may be segmented corresponding to the at least one supporting element 602. For example, the substrate receiving region 204 may include one or more further openings, e.g. one further opening in a center region and/or in a peripheral region of the substrate receiving region 204, in analogy to FIG. 5D or FIG. 6A, and one or more further supporting elements, e.g. in form of a pin, received in the one or more further openings. The at least one supporting element 602 may be detachable. For example, the at least one supporting element 602 may be received in the at least one opening 502, e.g. plugged in or screwed in.

The at least one supporting element 602 may form the at least one first recess portion 104a, 114a at least partially. The substrate receiving region 204 may further include at least two second recess portions, e.g. a peripheral second recess portion 104b′, 114b′ and a central recess portion 104b, 114b. The at least one first recess portion 104a, 114a may be disposed (or may extend) between the at least two second recess portions.

The at least one first recess portion 104a, 114a, e.g. the supporting element 602 (and/or further supporting elements, if present), may include a tapered shape (not shown). For example, the first supporting element 602a and/or the second supporting element 602b may be formed conical.

The at least one first recess portion 104a, 114a, e.g. the supporting element 602 (and/or further supporting elements, if present), may include a material, which is solid up to a temperature of greater than or equal to 1450° C., e.g. in the range from about 1450° C. to 1850° C., e.g. about 1630 C, e.g. a carbide material (e.g. SiC or TaC) and/or a carbon material (e.g. graphite), e.g. covered by the carbide material. Illustratively, the design of the substrate receiving region 204 enables to position a ring or a plurality of pins of suitable material (e.g. graphite, SiC. etc.), which support the wafer at its central region and/or at its peripheral region (e.g. at its rim), therewith furthermore lowering the friction between wafer holder and wafer, e.g. at the wafer rim.

FIG. 6C shows a substrate carrier 600c in a cross sectional view according to various embodiments. The substrate receiving region 204 may include at least one supporting element 602, e.g. in form of a ring 602a, 602b and/or including at least a first supporting element 602a and a second supporting element 602b. The at least one supporting element 602 may be detachable and disposed on a base surface of the substrate receiving region, e.g. in direct contact with. The base surface may be defined by the at least one second recess portion 104b, 114b. Illustratively, the opening is optionally not necessary for using the at least one supporting element 602. This may enable to easily modify certain substrate receiving region 204 geometries, as described herein. For example, the substrate receiving region 204 of the substrate carrier 600c may for example be similar to the substrate receiving region 204 of the substrate carrier 500b.

FIG. 6D shows a supporting element 602 in a top view according to various embodiments. The supporting element 602 may be ring shaped (e.g. a circular ring), e.g. including an opening 612 extending through the supporting element 602. The supporting element 602 may include a first portion 602a and a second portion 602b connected to each other, e.g. monolithically.

The supporting element 602 may be received in an opening 502 of the substrate receiving region 204 or alternatively disposed on a base surface of a recess portion 104b, 114b, 204. The opening 612 of the supporting element 602 may expose the base surface of a recess portion 104b, 114b, 204, e.g. a base surface of at least one second recess portion 104b, 114b. In other words, at least one second recess portion 104b, 114b may be disposed in the ring.

FIG. 7A shows two supporting elements 602, e.g. a first supporting element 602a and a second supporting element 602b, in a top view according to various embodiments. The first supporting element 602a and the second supporting element 602b may be substantially half-ring shaped (e.g. half of a circular ring), e.g. including an opening 612 extending through the supporting element 602. The first supporting element 602a and the second supporting element 602b may be separated from each other, e.g. by a gap 712.

The two supporting elements 602 may be received in an opening 502 of the substrate receiving region 204 or alternatively disposed on a base surface of a recess portion 104b, 114b, 204. The opening 612 and the gap 712 may expose the base surface of a recess portion 104b, 114b, 204, e.g. a base surface of at least one second recess portion 104b, 114b. In other words, at least one second recess portion 104b, 114b may separate the first supporting element 602a and the second supporting element 602b from each other.

FIG. 7B shows a plurality of supporting elements 602, e.g. including a first supporting element 602a, a second supporting element 602b, a third supporting element 602c and a fourth supporting element 602d, in a top view according to various embodiments. The plurality of supporting elements 602 may each be substantially quarter-ring shaped (e.g. quarter of a circular ring), e.g. including an opening 612 extending through the supporting element 602. The plurality of supporting elements 602 may each be separated from each other, e.g. by a gap 712.

The plurality of supporting elements 602 may be received in an opening 502 of the substrate receiving region 204 or alternatively disposed on a base surface of a recess portion 104b, 114b, 204. The opening 612 and the gap 712 may expose the base surface of a recess portion 104b, 114b, 204, e.g. a base surface of at least one second recess portion 104b, 114b. In other words, at least one second recess portion 104b, 114b may separate the plurality of supporting elements 602 from each other, e.g. at least pairwise.

FIG. 7C shows a plurality of supporting elements 602, e.g. including a first supporting element 602a and a second supporting element 602b and further supporting elements, in a top view according to various embodiments. The plurality of supporting elements 602 may each be circular shaped, e.g. surrounding an opening region 612 extending through the supporting element 602. The plurality of supporting elements 602 may each be separated from each other, e.g. by a gap 712. The opening 612 and the gap 712 may expose the base surface of a recess portion 104b, 114b, 204, e.g. a base surface of at least one second recess portion 104b, 114b. In other words, at least one second recess portion 104b, 114b may separate the plurality of supporting elements 602 from each other, e.g. at least pairwise.

FIG. 7D shows two supporting elements 602, e.g. including a first supporting element 602a and a second supporting element 602b. The two supporting elements 602 may each be circular shaped, e.g. being disposed distant from each other. The two supporting elements 602 may be separated from each other, e.g. by a gap 712. The gap 712 may expose the base surface of a recess portion 104b, 114b, 204, e.g. a base surface of at least one second recess portion 104b, 114b. In other words, at least one second recess portion 104b, 114b may separate the two supporting elements 602 from each other.

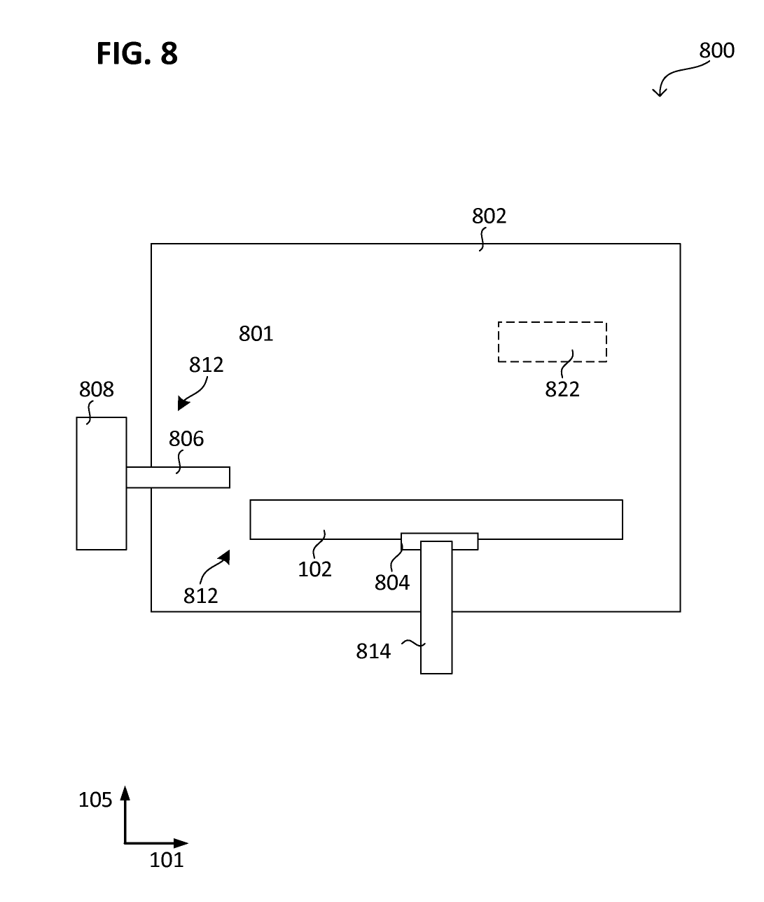

FIG. 8 shows a processing device 800 in a cross sectional view according to various embodiments. The processing device 800 may include a processing chamber 802, e.g. a vacuum chamber. The processing chamber 802 may be coupled with a pump system. The pump system may at least include a high vacuum pump and/or a pre-vacuum pump. The processing chamber 802 may be configured to provide a vacuum region 801 in the processing chamber 802. The processing device 800 may be configured to form a vacuum in the vacuum region 801.

Further, the processing device 800 may include a substrate carrier 812 as described herein. The substrate carrier 812 may include a carrier plate 102 including at least one substrate receiving region. Further, the substrate carrier 812 may include a mounting structure 804 configured to support the carrier plate 102.

Further, the processing device 800 may include a material source 812 configured to supply a gaseous material into the processing chamber. The gaseous material may include at least carbon (also referred as to gaseous carbon source). For example, the gaseous material may include or be formed from a carbon based gas, e.g. a polymer including carbon, e.g. hydrocarbon, e.g. propane and/or ethylene. Optionally, the material source 812 may further be configured to supply at least one of the following: a gaseous carrier (e.g. hydrogen and/or a noble gas), a gaseous doping source (e.g. a gas including nitrogen and/or aluminum, e.g. a metalorganic gas like trimethyl-aluminum or gaseous nitrogen), a gaseous silicon source (e.g. silane), a gaseous chloride source (a gas including chloride, e.g. methyltrichlorosilane, silicon tetrachloride and/or trichlorosilane). For example, the material source 812 may be configured to supply a gaseous carbon source, a gaseous silicon source, a gaseous doping source and a gaseous carrier (carrier gas), serially or at least partially parallel.

According to various embodiments, the material source 812 may include at least one gas support line 806 and at least one gas source 808 (coupled with the gas support line 806), e.g. at least one gas tank for each gaseous material (illustratively, for each gas). Optionally, the material source 812 may include a gas flow controller which is configured to control a gas flow based on a controlling parameter (e.g. inside the vacuum region and/or over the carrier plate 102). The controlling parameter may include at least one of the following: a pressure, a partial pressure, a gas flow rate (corresponding to a gas flow amount at least one of into or through the processing chamber 802 per time period), a gas flow velocity, a gas flow direction, a gas flow amount, a rotation speed of a substrate. The gas flow (e.g. at least one of its rate, velocity, direction, amount) and the process chamber pressure may be configured to control the rotational speed of the substrate, e.g. by adjusting at least one of the gas flow rate or the gas flow velocity.

At least one of the gas flow velocity or the gas flow amount may be defined by at least one of the gas pressure inside the processing chamber 802 or the gas flow rate at least one of into or through the processing chamber 802. At least one of the gas flow velocity or the amount of gas may be controlled by adjusting at least one of the gas pressure inside the processing chamber 802 or the gas flow rate at least one of into or through the processing chamber 802. The gas flow rate may be controlled by the gas flow controller, e.g. according to a predetermined controlling parameter, e.g. which may be adjusted to control the gas flow rate. For controlling the gas pressure inside the processing chamber 802 the processing device 800 may include a valve, e.g. a butterfly valve, which may control the coupling of the processing chamber 802 with a pump arrangement. For example, the pump arrangement may be connected to the processing chamber 802 by an exhaust line in which the valve may be disposed. By closing the valve, the coupling between the pump arrangement and the processing chamber 802 may be reduced, such that the suction power provided to the processing chamber 802 may be reduced. By opening the valve, the coupling between the pump arrangement and the processing chamber 802 may be increased, such that the suction power provided to the processing chamber 802 may be increased. A maximum suction power may be provided to the processing chamber 802 at a completely opened valve configuration leading to a minimum gas pressure inside the processing chamber 802 (in other words, the processing chamber 802 may be fully coupled with the pump arrangement). A minimum suction power may be provided to the processing chamber 802 at a completely closed valve configuration leading to a maximum gas pressure inside the processing chamber 802 (in other words, the processing chamber 802 may be fully decoupled from the pump arrangement). By reducing the gas pressure inside the processing chamber 802 at least one of the gas flow velocity or the gas flow rate may be increased.

The activation torque of the wafer, which represents the minimal torque (illustratively, necessary to be applied to the wafer) for activating a rotation of the wafer, may be defined by a friction between the wafer and the substrate carrier. The torque applied to the wafer may be defined by a friction between the gas flow and the wafer and may be controlled by adjusting at least one of the gas flow rate at least one of into or through the processing chamber 802, the gas flow velocity at least one of into or through the processing chamber 802, or the gas pressure inside the processing chamber 802. Illustratively, to activate the rotation of the wafer the torque applied to the wafer (by the gas flow) may be greater than the activation torque, e.g. resulting in a transfer of kinetic energy to the wafer, e.g. increasing the rotational energy of the wafer. The torque applied to the wafer may be increased by increasing the gas flow rate at least one of into or through the processing chamber 802. Alternatively or additionally, the torque applied to the wafer may be increased by increasing the gas flow velocity at least one of into or through the processing chamber 802. Alternatively or additionally, the torque applied to the wafer may be increased by reducing the gas pressure inside the processing chamber 802.

Optionally, the processing device 800 may include a heater system 822 configured to heat the substrate carrier to a temperature of greater than or equal to 1450° C., e.g. in the range from about 1450° C. to 1850° C., e.g. about 1630 C. The heater system 822 may include at least one of a radiation source (e.g. a heat radiation source or a light source, e.g. a laser), an induction heating element, an electric resistance heating element. For reaching higher temperatures, e.g. in the range from about 1450° C. to 1850° C., at least one of an induction heating element or an electric resistance heating element may be used. The heater system 822 may be electrically connected to a power supply. The heater system 822 may be configured to transfer thermal energy to the substrate carrier 812 and/or to one or more substrates received in the substrate carrier 812.

Optionally, the processing device 800 may include an actuation system 814 coupled with the carrier plate mounting structure 804 and configured to rotate the substrate carrier. For example, the actuation system 814 may include a motor and a shaft. The shaft may couple the motor with the carrier plate mounting structure 804 for transferring a torque generated by the motor to the carrier plate mounting structure 804.

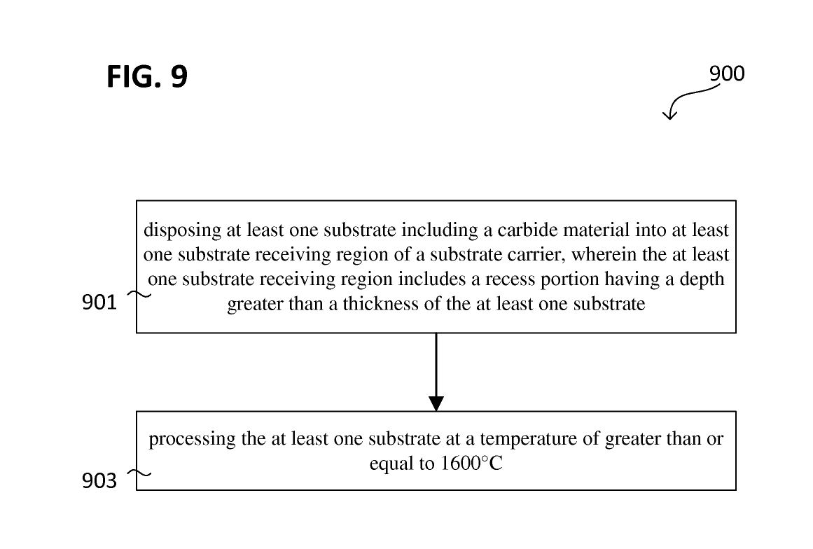

FIG. 9 shows a method 900 in a schematic flow diagram according to various embodiments.

The method 900 may include in 901 disposing at least one substrate including a carbide material into at least one substrate receiving region of a substrate carrier, wherein the at least one substrate receiving region includes at least one recess portion (also referred to as at least one second recess portion) having a depth (also referred to as second depth) greater than a thickness of the at least one substrate. The method 900 may include in 903 processing the at least one substrate at a temperature of greater than or equal to 1450° C., e.g. in the range from about 1450° C. to 1850° C., e.g. about 1630 C.

Processing the at least one substrate may include forming at least one layer, e.g. including SiC, on the at least one substrate. Forming the at least one layer may include a reaction of a gaseous material with the at least one substrate, e.g. including or formed from a gaseous carbon source and/or a gaseous silicon source. In other words, the gaseous material (gas) may include at least carbon and/or at least silicon. Alternatively or additionally, processing the at least one substrate may include doping the at least one substrate at least partially. Therefore, a gaseous material including or formed from a gaseous doping source may be applied to the at least one substrate.

According to various embodiments, the substrate carrier may include at least carbon in form of a carbide and/or in form of graphite. The carbon may be in form of a carbide (carbide material) and/or in form of graphite (graphite material). The carrier plate 102 may include or be formed from carbon, e.g. in the form of graphite, and/or coated by carbide material, e.g. silicon carbide and/or tantalum carbide. The at least one substrate may include SiC, e.g. in monocrystalline form.

The method may optionally include rotating the at least one substrate. In this case the at least one substrate receiving region may include a circular shape. In other words, the at least one substrate receiving region may include circular-shaped cross section parallel to the lateral plate plane, e.g. a circular perimeter (circumference). For rotating the at least one substrate, a gas flow (flow of gas) may be formed over the at least one substrate, e.g. the gas flow may be provided and/or controlled by a material source. The gas flow may transfer mechanical energy (e.g. kinetic energy) to the at least one substrate. In other words, the gas flow may causes (e.g. apply) a torque (e.g. a force) to the at least one substrate. The torque may be caused from friction between the gas molecules and the at least one substrate. The material source may be configured to provide a flow of the gaseous material (gas flow) over the substrate carrier, such that the at least one substrate received in the substrate carrier is activated to rotate.

The gas flow may have a velocity (flow velocity) which defines a force which the gas flow applies to the at least one substrate. The force may define a torque which the gas flow applies to the at least one substrate. To rotate the at least one substrate, the torque applied to the at least one substrate may overcome the resistance occurring from friction between the at least one substrate and the substrate carrier. When the substrate rotates, it receives mechanical energy from the gas flow, e.g. kinetic energy.

According to various embodiments, the recess portion may define a base surface being in contact to the at least one substrate. In this case, the at least one substrate receiving region may be recessed deeper than the thickness of the at least one substrate and/or the sidewall of the at least one substrate receiving region (at its perimeter) may include an extension (perpendicular to the plate plane) greater that the thickness of the at least one substrate. Illustratively, the at least one substrate may be flush-mounted in the at least one substrate receiving region. A difference between the thickness of the at least one substrate and the depth of the recess portion may be greater than about 50 μm, e.g. greater than about 75 μm, e.g. greater than about 100 μm, e.g. greater than about 150 μm, e.g. greater than about 200 μm, e.g. greater than about 250 μm, e.g. greater than about 300 μm, e.g. in the range from about 50 μm to 300 μm, e.g. in the range from about 100 μm to 200 μm.

The substrate receiving region may include at least one further recess portion (also referred to as at least one first recess portion) having a further depth (also referred to as first depth), the depth being different from (e.g. greater or less than) the further depth, wherein the further depth is optionally greater than or equal to the thickness of the wafer. The at least one further recess portion may define a base surface being in contact to the at least one substrate (wafer). In other words, the at least one substrate may be supported by the at least one further recess portion. In this case, the at least one substrate may be substantially flush-mounted with a surface of the substrate carrier, e.g. a surface of its carrier plate.

According to various embodiments, an epitaxial SiC layer may be formed on or over the at least one substrate (also referred as to epitaxial process). The wafer may include a carbide material, e.g. SiC. For forming the epitaxial SiC layer, the wafer may be heated to process temperature, e.g. temperatures greater than 1450° C., e.g. in the range from about 1450° C. to 1850° C., e.g. about 1630 C.

The at least one second recess portion may be arranged in an edge region (step region) of the carrier plate and/or between an edge of the carrier plate and the at least one first recess portion. Alternatively or additionally, the at least one first recess portion may be arranged in an edge region (step region) of the carrier plate and/or between an edge of the carrier plate and the at least one second recess portion.

The at least one first recess portion may provide a substrate support. In other words, a substrate received in the at least one substrate receiving region may be supported by the at least one first recess portion, e.g. in physical contact with the at least one first recess portion and/or in a peripheral region of the substrate. The at least one first recess portion may protrude from a base surface of the at least one substrate receiving region, such that a gap is formed at least partially between the base surface and a substrate received in the at least one substrate receiving region.

Further, various embodiments will be described in the following:

1. A substrate carrier may include:
a carrier plate including a plurality of substrate receiving regions;
each substrate receiving region may include at least one first recess portion having a first depth and at least one second recess portion having a second depth, the second depth being greater than the first depth; and
a carrier plate mounting structure configured to support the carrier plate.

2. The substrate carrier of clause 1,
wherein the at least one second recess portion at least partially surrounds the at least one first recess portion.

3. The substrate carrier of clause 1,
wherein the at least one first recess portion at least partially surrounds the at least one second recess portion.

4. The substrate carrier of one of the clauses 1 to 3,
wherein a difference between the first depth and the second depth is greater than about 50 μm.

5. The substrate carrier of one of the clauses 1 to 4, wherein a perimeter shape of each substrate receiving region may include a
curved portion and a non-curved portion.

6. The substrate carrier of one of the clauses 1 to 4,
wherein a perimeter shape of each substrate receiving region is circular.

7. The substrate carrier of one of the clauses 1 to 6,
wherein a perimeter shape of the at least one first recess portion and/or of the at least one second recess portion is circular.

8. The substrate carrier of one of the clauses 1 to 7,
wherein the at least one first recess portion is monolithically connected with the carrier plate; or
wherein each substrate receiving region includes at least one detachable supporting element forming the at least one first recess portion at least partially.

9. The substrate carrier of clause 8,
wherein each substrate receiving region includes at least one opening in
which the at least one supporting element is received.

10. The substrate carrier of one of the clauses 1 to 9,
wherein the least one first recess portion includes a tapered shape.

11. The substrate carrier of one of the clauses 1 to 10,
wherein the carrier plate includes a solid material up to a temperature of greater than or equal to 1450° C.

12. The substrate carrier of clause 11,
wherein the solid material includes carbon.

13. The substrate carrier of one of the clauses 1 to 12,
wherein a surface property of the carrier plate in each substrate receiving region differs from a surface property of the carrier plate outside each substrate receiving region.

14. The substrate carrier of one of the clauses 1 to 13,
wherein a surface property of the at least one first recess portion differs from
a surface property of the at least one second recess portion.

15. The substrate carrier of one of the clauses 1 to 14,
wherein a sidewall of the at least one first recess portion and/or of the at least one second recess portion is slanted.

16. The substrate carrier of one of the clauses 1 to 15,
wherein the carrier plate includes a circular-shaped cross section parallel to a lateral plate plane.

17. The substrate carrier of one of the clauses 1 to 16,
wherein each substrate receiving region includes a lateral extension of greater than or equal to about 100 mm.

18. The substrate carrier of one of the clauses 1 to 17,
wherein each substrate receiving region includes a lateral extension of greater than or equal to about 150 mm.

19. The substrate carrier of one of the clauses 1 to 18,
wherein each substrate receiving region includes a lateral extension of less than or equal to about 200 mm.

20. The substrate carrier of one of the clauses 1 to 19,
wherein the first depth is less than or equal to about 400 μm.

21. The substrate carrier of one of the clauses 1 to 20,
wherein the second depth is greater than about 400 μm.

22. The substrate carrier of one of the clauses 1 to 21,
wherein a lateral extension of the at least one first recess portion is in the range of about 0.1 mm to about 25 mm.

23. The substrate carrier of one of the clauses 1 to 22,
wherein the carrier plate includes a lateral extension greater than about 300 mm.

24. The substrate carrier of one of the clauses 1 to 23,
wherein each substrate receiving region is terraced.

25. The substrate carrier of one of the clauses 11 to 24,
wherein the solid material includes a state of matter transition temperature of greater than or equal to 1450° C.

26. The substrate carrier of one of the clauses 1 to 25,
wherein each substrate receiving region includes at least one third recess portion having a third depth, the first depth being greater than the third depth and/or the second depth being greater than the third depth;
wherein the at least one first recess portion and/or the at least one second recess portion at least partially surrounds the at least one third recess portion.

27. The substrate carrier of one of the clauses 1 to 26,
wherein the carrier plate is covered by a carbide material.

28. The substrate carrier of clause 27,
wherein the carbide material is silicon carbide and/or tantalum carbide.

29. The substrate carrier of one of the clauses 13 to 28,
wherein a surface property includes at least one of: a texture, a chemical composition, a roughness, a surface tension, a topology.

30. A substrate carrier including:
a carrier plate including at least one substrate receiving region including at least one first recess portion having a first depth and at least one second recess portion having a second depth, the second depth being greater than the first depth;
wherein the at least one second recess portion at least partially surrounds the at least one first recess portion; and
a carrier plate mounting structure configured to support the carrier plate.

31. The substrate carrier of clause 30,
wherein a perimeter shape of the at least one substrate receiving region includes a curved portion and a non-curved portion.

32. The substrate carrier of clause 30,
wherein a perimeter shape of the at least one substrate receiving region is circular.

33. The substrate carrier of one of the clauses 30 to 32,
wherein a perimeter shape of the at least one first recess portion and/or of the at least one second recess portion is circular.

34. The substrate carrier of one of the clauses 30 to 33,
wherein the at least one first recess portion is monolithically connected with the carrier plate; or
wherein the at least one substrate receiving region includes at least one detachable supporting element forming the at least one first recess portion at least partially.

35. The substrate carrier of clause 34,
wherein the at least one substrate receiving region includes at least one opening in which at least one supporting element is received.

36. The substrate carrier of one of the clauses 30 to 35,
wherein the least one first recess portion includes a tapered shape.

37. The substrate carrier of one of the clauses 30 to 36,
wherein the carrier plate includes a solid material up to a temperature of greater than or equal to 1450° C.

38. The substrate carrier of clause 37,
wherein the solid material includes carbon.

39. The substrate carrier of one of the clauses 30 to 38,
wherein a surface property of the carrier plate in the at least one substrate receiving region differs from a surface property of the carrier plate outside the at least one substrate receiving region.

40. The substrate carrier of one of the clauses 30 to 39,
wherein a surface property of the at least one first recess portion differs from a surface property of the at least one second recess portion.

41. The substrate carrier of one of the clauses 30 to 40,
wherein a sidewall of the at least one first recess portion and/or of the at least one second recess portion is slanted.

42. The substrate carrier of one of the clauses 30 to 41,
wherein the carrier plate includes a circular-shaped cross section parallel to a plate plane.

43. The substrate carrier of one of the clauses 30 to 42,
wherein the at least one substrate receiving region includes a lateral extension of greater than or equal to about 100 mm.

44. The substrate carrier of one of the clauses 30 to 43,
wherein the at least one substrate receiving region includes a lateral extension of greater than or equal to about 150 mm.

45. The substrate carrier of one of the clauses 30 to 44,
wherein the at least one substrate receiving region includes a lateral extension of less than or equal to about 200 mm.

46. The substrate carrier of one of the clauses 30 to 45,
wherein the first depth is less than or equal to about 400 μm.

47. The substrate carrier of one of the clauses 30 to 46,
wherein the second depth is greater than about 400 μm.

48. The substrate carrier of one of the clauses 30 to 47,
wherein a difference between the first depth and the second depth greater than about 50 μm.

49. The substrate carrier of one of the clauses 30 to 48,
wherein a lateral extension of the at least one first recess portion is in the range of about 0.1 mm to about 25 mm.

50. The substrate carrier of one of the clauses 30 to 49,
wherein the carrier plate includes a lateral extension of greater than about 300 mm.

51. The substrate carrier of one of the clauses 30 to 50,
wherein the at least one substrate receiving region is terraced.

52. The substrate carrier of one of the clauses 30 to 51,
wherein the solid material includes a state of matter transition temperature of greater than or equal to 1450° C.

53. The substrate carrier of one of the clauses 30 to 52,
wherein the at least one substrate receiving region includes at least one third recess portion having a third depth, the first depth being greater than the third depth and/or the second depth being greater than the third depth;
wherein the at least one first recess portion at least partially surrounds the at least one third recess portion.

54. The substrate carrier of one of the clauses 30 to 53,
wherein the carrier plate is covered by a carbide material.

55. The substrate carrier of clause 54,
wherein the carbide material is silicon carbide or tantalum carbide.

56. The substrate carrier of one of the clauses 39 to 55,
wherein a surface property includes at least one of: a texture, a chemical composition, a roughness, a surface tension, a topology.

57. A substrate carrier including:
a carrier plate including a plurality of substrate receiving regions;
(a) wherein each substrate receiving region includes a recess portion having a depth of greater than about 500 μm; and wherein each substrate receiving region includes lateral extension of less than or equal to about 200 mm; or
(b) wherein each substrate receiving region includes a recess portion having a depth; and wherein each substrate receiving region includes lateral extension, wherein a ratio of the depth to the lateral extension is greater than or equal to about 2.5·10⁻³; or
(c) wherein each substrate receiving region includes a recess portion having a depth of greater than about 400 μm; and wherein each substrate receiving region includes lateral extension of less than or equal to about 150 mm.

58. The substrate carrier of clause 57,
wherein the each substrate receiving region includes a further recess portion having a depth of less than about 400 μm.

59. The substrate carrier of clause 57 or 58,
wherein a perimeter shape of the at least one substrate receiving region includes a curved portion and a non-curved portion.

60. The substrate carrier of one of the clauses 57 to 59,
wherein a perimeter shape of the at least one substrate receiving region is circular.

61. The substrate carrier of one of the clauses 57 to 60,
wherein a perimeter shape of the at least one recess portion is circular.

62. The substrate carrier of one of the clauses 58 to 60,
wherein a perimeter shape of the at least one further recess portion is circular.

63. The substrate carrier of one of the clauses 58 to 62,
wherein the at least one further recess portion is monolithically connected with the carrier plate; or
wherein the at least one substrate receiving region includes at least one detachable supporting element forming the at least one further recess portion at least partially.

64. The substrate carrier of clause 63,
wherein the at least one substrate receiving region includes at least one opening in which at least one supporting element is received.

65. The substrate carrier of one of the clauses 58 to 63,
wherein the least one further recess portion includes a tapered shape.

66. The substrate carrier of one of the clauses 58 to 65,
wherein the carrier plate includes a solid material up to a temperature of greater than or equal to 1450° C.

67. The substrate carrier of clause 66,
wherein the solid material includes carbon.

68. The substrate carrier of one of the clauses 57 to 67,
wherein a surface property of the carrier plate in at least one substrate receiving region of the plurality of substrate receiving regions differs from a surface property of the carrier plate outside the at least one substrate receiving region.

69. The substrate carrier of one of the clauses 58 to 68,
wherein a surface property of the at least one recess portion differs from a surface property of the at least one further recess portion.

70. The substrate carrier of one of the clauses 57 to 69,
wherein a sidewall of the at least one recess portion is slanted.

71. The substrate carrier of one of the clauses 58 to 70,
wherein a sidewall of the at least one further recess portion is slanted.

72. The substrate carrier of one of the clauses 57 to 71,
wherein the carrier plate includes a circular-shaped cross section parallel to a plate plane.

73. The substrate carrier of one of the clauses 57 to 72,
wherein the at least one substrate receiving region includes a lateral extension of greater than or equal to about 100 mm.

74. The substrate carrier of one of the clauses 57 to 73,
wherein the at least one substrate receiving region includes a lateral extension of greater than or equal to about 150 mm.

75. The substrate carrier of one of the clauses 57 to 74,
wherein the at least one substrate receiving region includes a lateral extension of less than or equal to about 200 mm.

76. The substrate carrier of one of the clauses 57 to 75,
wherein the first depth is less than or equal to about 400 μm.

77. The substrate carrier of one of the clauses 57 to 76,
wherein the second depth is greater than about 400 μm.

78. The substrate carrier of one of the clauses 58 to 77,
wherein a difference between the depth of the at least one recess portion and a depth of the at least one further recess portion is greater than about 50 μm.

79. The substrate carrier of one of the clauses 58 to 78,
wherein a lateral extension of the at least one further recess portion is in the range of about 0.1 mm to about 25 mm.

80. The substrate carrier of one of the clauses 57 to 79,
wherein the carrier plate includes a lateral extension of greater than about 300 mm.

81. The substrate carrier of one of the clauses 57 to 80,
wherein the at least one substrate receiving region is terraced.

82. The substrate carrier of one of the clauses 57 to 81,
wherein the solid material includes a state of matter transition temperature of greater than or equal to 1450° C.

83. The substrate carrier of one of the clauses 57 to 82,
wherein the carrier plate is covered by a carbide material.

84. The substrate carrier of clause 83,
wherein the carbide material is silicon carbide or tantalum carbide.

85. The substrate carrier of one of the clauses 57 to 84,
wherein a surface property includes at least one of: a texture, a chemical composition, a roughness, a surface tension, a topology.

86. A processing device including:
a processing chamber;
a substrate carrier disposed in the processing chamber and including at least one substrate receiving region;
a material source configured to supply a gaseous material into the processing chamber, the gaseous material including at least carbon.

87. The processing device of clause 86,
wherein the at least one substrate receiving region includes at least one recess portion;
wherein a depth of the at least one recess portion is greater than about 400 μm; or wherein the at least one substrate receiving region includes at least one further recess portion having a depth different from (in other words, less or greater than) the depth of at least one recess portion.

88. The processing device of clause 86 or 87,
wherein the substrate carrier is configured according to one of the clauses 1 to 85.

89. The processing device of one of the clauses 86 to 88, further including:
a heater system configured to heat the substrate carrier to a temperature of greater than or equal to 1450° C.

90. The processing device of one of the clauses 86 to 89, further including:
an actuation system coupled with the carrier plate mounting structure and configured to rotate the substrate carrier.

91. The processing device of one of the clauses 86 to 90,
wherein the material source is configured to provide a flow of the gaseous material over the substrate carrier, such that mechanical energy is transferred from the gaseous material to the at least one substrate.

92. A method including:
disposing at least one substrate including a carbide material into at least one substrate receiving region of a substrate carrier, wherein the at least one substrate receiving region includes at least one recess portion having a depth greater than a thickness of the at least one substrate; and
processing the at least one substrate at a temperature of greater than or equal to 1450° C.

93. The method of clause 92,
wherein processing the at least one substrate includes forming at least one layer including SiC on the at least one substrate and/or doping the at least one substrate at least partially.

94. The method of clause 92 or 93,
wherein the at least one substrate includes SiC.

95. The method of one of the clauses 92 to 94,
wherein the substrate carrier includes a material which is solid up to a temperature of greater than or equal to 1450° C.

96. The method of clause 95,
wherein the substrate carrier includes at least carbon.

97. The method of one of the clauses 92 to 96,
rotating the at least one substrate at least during processing the substrate.

98. The method of one of the clauses 92 to 97,
wherein rotating the at least one substrate includes forming a gas flow over the at least one substrate for transferring mechanical energy from the gas flow to the at least one substrate.

99. The method of one of the clauses 92 to 98,
wherein the recess portion defines a base surface being in contact to the at least one substrate.

100. The method of one of the clauses 92 to 99,
wherein a difference between the thickness of the at least one substrate and the depth of the recess portion is greater than about 50 μm.

101. The method of one of the clauses 92 to 100,
wherein the substrate receiving region includes at least one further recess portion having a further depth, the depth being greater than the further depth,
wherein the further depth is greater than or equal to the thickness of the wafer.

102. The method of clause 101,
wherein the at least one further recess portion defines a base surface being in contact to the at least one substrate.

103. The method of one of the clauses 92 to 102,
wherein the at least one substrate includes carbon.

104. The method of one of the clauses 92 to 103,
wherein the at least one substrate includes a semiconductor material including carbon.

105. The method of one of the clauses 92 to 104,
wherein the at least one substrate includes SiC.

106. The method of one of the clauses 92 to 105,
wherein the substrate carrier includes carbon in form of a carbide and/or in form of graphite.

107. The method of one of the clauses 92 to 106,
wherein the at least one substrate receiving region includes at least one further recess portion having a depth substantially equal to the thickness of the at least one substrate.

108. The method of one of the clauses 92 to 107,
wherein the at least one substrate receiving region includes at least one further recess portion having a depth less than the depth of the at least one recess portion.

109. The method of one of the clauses 92 to 106,
wherein the at least one substrate receiving region includes at least one further recess portion having a depth greater than a thickness of the at least one substrate and less than the depth of the at least one recess portion.

109. A substrate carrier including:
a carrier plate including a plurality of substrate receiving regions;
wherein each substrate receiving region includes a recess portion having a depth of greater than about 400 μm;
wherein each substrate receiving region includes a lateral extension of less than or equal to about 200 mm.

110. The substrate carrier of clause 109,
wherein each substrate receiving region includes a lateral extension of less than 200 mm.

111. The substrate carrier of clause 109,
wherein each substrate receiving region includes a lateral extension of less than or equal to about 150 mm.

112. A substrate carrier including:
a carrier plate including a plurality of substrate receiving regions;
wherein each substrate receiving region includes a recess portion having a depth of greater than about 500 μm;
wherein each substrate receiving region includes a lateral extension of less than or equal to about 250 mm.

113. The substrate carrier of clause 112,
wherein each substrate receiving region includes a lateral extension of less than 250 mm.

114. The substrate carrier of clause 112,
wherein each substrate receiving region includes a lateral extension of less than or equal to about 200 mm.

What is claimed is:

1. A substrate carrier comprising:
a carrier plate comprising a plurality of substrate receiving regions;
each substrate receiving region comprising at least one first recess portion having a first depth and at least one second recess portion having a second depth, the second depth being greater than the first depth; and
a carrier plate mounting structure configured to support the carrier plate.

2. The substrate carrier of claim 1,
wherein the at least one second recess portion at least partially surrounds the at least one first recess portion.

3. The substrate carrier of claim 1,
wherein the at least one first recess portion at least partially surrounds the at least one second recess portion.

4. The substrate carrier of claim 1,
wherein a difference between the first depth and the second depth is greater than about 50 μm.

5. The substrate carrier of claim 1,
wherein a perimeter shape of each substrate receiving region comprises a curved portion and a non-curved portion.

6. The substrate carrier of claim 1,
wherein a perimeter shape of each substrate receiving region is circular.

7. The substrate carrier of claim 1,
wherein the least one first recess portion comprises a tapered shape.

8. The substrate carrier of claim 1,
wherein the carrier plate comprises a solid material up to a temperature of greater than or equal to 1450° C.

9. The substrate carrier of claim 1,
wherein a surface property of the carrier plate in each substrate receiving region differs from a surface property of the carrier plate outside each substrate receiving region.

10. The substrate carrier of claim 1,
wherein a surface property of the at least one first recess portion differs from a surface property of the at least one second recess portion.

11. The substrate carrier of claim 1,
wherein a sidewall of the at least one first recess portion and/or of the at least one second recess portion is slanted.

12. A substrate carrier comprising:
a carrier plate comprising at least one substrate receiving region comprising at least one first recess portion having a first depth and at least one second recess portion having a second depth, the second depth being greater than the first depth;
wherein the at least one second recess portion at least partially surrounds the at least one first recess portion; and
a carrier plate mounting structure configured to support the carrier plate.

13. The substrate carrier of claim 12,
wherein a perimeter shape of the at least one substrate receiving region comprises a curved portion and a non-curved portion.

14. The substrate carrier of claim 12,
wherein a perimeter shape of the at least one substrate receiving region is circular.

15. The substrate carrier of claim 12,
wherein a perimeter shape of the at least one first recess portion and/or of the at least one second recess portion is circular.

16. A substrate carrier comprising:
a carrier plate comprising a plurality of substrate receiving regions;
wherein each substrate receiving region comprises a recess portion having a depth; and
wherein each substrate receiving region comprises lateral extension, wherein a ratio of the depth to the lateral extension is greater than or equal to about 2.5.10.

17. A processing device comprising:
a processing chamber;
a substrate carrier disposed in the processing chamber and comprising at least one substrate receiving region,
wherein the substrate receiving region comprises at least one recess portion;
wherein a depth of the at least one recess portion is greater than about 400 μm; or
wherein the at least one substrate receiving region comprises at least one further recess portion having a depth different from the depth of at least one recess portion; and
a material source configured to supply a gaseous material into the processing chamber, the gaseous material comprising at least carbon.

18. The processing device of claim 17, further comprising:
a heater system configured to heat the substrate carrier to a temperature of greater than or equal to 1450° C.

19. The processing device of claim 17, further comprising:
an actuation system coupled with the carrier plate mounting structure and configured to rotate the substrate carrier.

20. The processing device of claim 17,
wherein the material source is configured to provide a flow of the gaseous material over the substrate carrier, such that mechanical energy is transferred from the gaseous material to the at least one substrate.
